(19) United States
(12) Patent Application Publication
(10) Pub. No.: US 2026/0143700 A1
(43) Pub. Date: May 21, 2026

(54) THREE-DIMENSIONAL MEMORY DEVICE WITH LOCALIZED ISOLATION TRENCH WIDENING AND METHODS FOR FORMING THE SAME

(71) Applicant: Sandisk Technologies, Inc., Milpitas, CA (US)

(72) Inventor: Atsushi SHIMIZU, Yokkaichi (JP)

(21) Appl. No.: 18/949,370

(22) Filed: Nov. 15, 2024

(51) Int. Cl. H10B 43/27

(52) U.S. Cl. CPC H10B 43/27

(57) ABSTRACT

A device structure includes a pair of vertical layer stacks containing alternating insulating and electrically conductive layers that laterally extend along a first horizontal direction and are laterally spaced apart from each other along a second horizontal direction by a lateral isolation trench that is filled with a lateral isolation trench fill structure, memory openings vertically extending through a respective vertical layer stack within the pair of vertical layer stacks, memory opening fill structures located in the memory openings, where each of the memory opening fill structures includes a respective vertical stack of memory elements and a vertical semiconductor channel, and support pillar structures vertically extending through the pair of vertical layer stacks. Dielectric bridges connect a first subset of the support pillar structures with the lateral isolation trench fill structure.

### FIELD

The present disclosure relates generally to the field of semiconductor devices, and particularly to a three-dimensional memory device employing localized lateral isolation trench widening and methods for forming the same.

### BACKGROUND

A three-dimensional memory device can include an alternating stack of insulating layers and electrically conductive layers. A reliable method is desired for forming layer contact via structures for each of the electrically conductive layers without generating electrical shorts between neighboring pairs of electrically conductive layers.

### SUMMARY

According to an aspect of the present disclosure, a device structure includes a pair of vertical layer stacks containing alternating insulating and electrically conductive layers that laterally extend along a first horizontal direction and are laterally spaced apart from each other along a second horizontal direction by a lateral isolation trench that is filled with a lateral isolation trench fill structure, memory openings vertically extending through a respective vertical layer stack within the pair of vertical layer stacks, memory opening fill structures located in the memory openings, where each of the memory opening fill structures includes a respective vertical stack of memory elements and a vertical semiconductor channel, and support pillar structures vertically extending through the pair of vertical layer stacks. Dielectric bridges connect a first subset of the support pillar structures with the lateral isolation trench fill structure.

According to another aspect of the present disclosure, a method of forming a device structure comprises: forming a pair of vertical layer stacks embedding memory opening fill structures over a substrate, wherein the vertical layer stacks laterally extend along a first horizontal direction and are laterally spaced apart from each other along a second horizontal direction by a lateral isolation trench, wherein each vertical layer stack within the pair of vertical layer stacks comprises, from bottom to top, a respective first-tier alternating stack of first-tier insulating layers and first-tier sacrificial material layers, a respective first-tier insulating cap layer embedding first sacrificial plates, a respective second-tier alternating stack of second-tier insulating layers and second-tier sacrificial material layers, and a respective second-tier insulating cap layer, and wherein each of the memory openings vertically extends through a respective vertical layer stack within the pair of vertical layer stacks and comprises a respective vertical stack of memory elements; forming first laterally-extending voids by removing the first sacrificial plates selectively to the first-tier insulating cap layer, the first-tier alternating stack, and the second-tier alternating stack; selectively etching lower portions of the second-tier alternating stacks without etching upper portions of the second-tier alternating stacks and without etching upper portions of the first-tier alternating stacks, wherein the lateral isolation trench is widened at a level of the lower portions of the second-tier alternating stacks; and replacing the first-tier sacrificial material layers and the second-tier sacrificial material layers with first-tier electrically conductive layers and second-tier electrically conductive layers, respectively.

### BRIEF DESCRIPTION OF THE DRAWINGS

FIGS. 1A-1D are sequential vertical cross-sectional views of a region of an exemplary structure during formation of source-level material layers and source-select-level sacrificial plates according to an embodiment of the present disclosure.

FIG. 2 is a vertical cross-sectional view of the exemplary structure after formation of a first-tier alternating stack of first-tier insulating layers and first sacrificial material layers, first stepped surfaces, and a first retro-stepped dielectric material portion according to an embodiment of the present disclosure.

FIG. 3A is a vertical cross-sectional view of a region of the exemplary structure after formation of first-tier memory openings and first-tier sacrificial memory opening fill structures according to an embodiment of the present disclosure. FIG. 3B is a top-down view of a region of the exemplary structure of FIG. 3A.

FIG. 4A is a vertical cross-sectional view of a region of the exemplary structure after formation of a first-tier insulating cap layer, first-tier support openings, first-tier lateral isolation trenches, and first-tier contact openings according to an embodiment of the present disclosure. FIG. 4B is a top-down view of a region of the exemplary structure of FIG. 4A.

FIG. 5A is a vertical cross-sectional view of a region of the exemplary structure after formation of first-tier sacrificial support opening fill structures, first-tier sacrificial lateral isolation trench fill structures, first-tier sacrificial contact opening fill structures, and first-tier cap-level recess cavities according to an embodiment of the present disclosure. FIG. 5B is a top-down view of a region of the exemplary structure of FIG. 5A.

FIG. 6A is a vertical cross-sectional view of a region of the exemplary structure after formation of first sacrificial plates according to an embodiment of the present disclosure. FIG. 6B is a top-down view of a region of the exemplary structure of FIG. 6A.

FIG. 7 is a vertical cross-sectional view of the exemplary structure after formation of a second-tier alternating stack of second-tier insulating layers and second sacrificial material layers, second stepped surfaces, a second retro-stepped dielectric material portion, second-tier memory openings, and second-tier sacrificial memory opening fill structures according to an embodiment of the present disclosure.

FIG. 8 is a vertical cross-sectional view of a region of the exemplary structure after formation of a second-tier insulating cap layer, second-tier support openings, second-tier lateral isolation trenches, and second-tier contact openings according to an embodiment of the present disclosure.

FIG. 9 is a vertical cross-sectional view of a region of the exemplary structure after formation of second-tier sacrificial support opening fill structures, second-tier sacrificial lateral isolation trench fill structures, and second-tier sacrificial contact opening fill structures according to an embodiment of the present disclosure.

FIG. 10 is a vertical cross-sectional view of a region of the exemplary structure after formation of second-tier cap-level recess cavities according to an embodiment of the present disclosure.

FIG. 11 is a vertical cross-sectional view of a region of the exemplary structure after formation of second sacrificial plates according to an embodiment of the present disclosure.

FIG. 12 is a vertical cross-sectional view of the exemplary structure after formation of a third-tier alternating stack of third-tier insulating layers and third sacrificial material layers, third stepped surfaces, a third retro-stepped dielectric material portion, and third-tier memory openings according to an embodiment of the present disclosure.

FIG. 13 is a vertical cross-sectional view of the exemplary structure after formation of inter-tier memory openings according to an embodiment of the present disclosure.

FIGS. 14A-14D are sequential vertical cross-sectional views of a region around an inter-tier memory opening during formation of a memory opening fill structure according to an embodiment of the present disclosure.

FIG. 15 is a vertical cross-sectional view of a region of the exemplary structure after formation of a third-tier insulating cap layer according to an embodiment of the present disclosure.

FIG. 16A is a vertical cross-sectional view of a region of the exemplary structure after formation of third-tier support openings, third-tier lateral isolation trenches, and third-tier contact openings according to an embodiment of the present disclosure. FIG. 16B is a top-down view of a region of the exemplary structure of FIG. 16A.

FIG. 17A is a vertical cross-sectional view of a region of the exemplary structure after formation of third-tier sacrificial support opening fill structures, third-tier sacrificial lateral isolation trench fill structures, and third-tier sacrificial contact opening fill structures according to an embodiment of the present disclosure. FIG. 17B is a top-down view of a region of the exemplary structure of FIG. 17A.

FIG. 18A is a vertical cross-sectional view of a region of the exemplary structure after formation of a first contact-level dielectric layer and discrete holes according to an embodiment of the present disclosure. FIG. 18B is a top-down view of a region of the exemplary structure of FIG. 18A.

FIG. 19A is a vertical cross-sectional view of a region of the exemplary structure after formation of inter-tier support openings according to an embodiment of the present disclosure. FIG. 19B is a top-down view of a region of the exemplary structure of FIG. 19A.

FIGS. 20A-20D are sequential vertical cross-sectional views of a region of the exemplary structure during formation of insulating fins according to an embodiment of the present disclosure.

FIG. 21A is a vertical cross-sectional view of a region of the exemplary structure after formation of the insulating fins around inter-tier support openings according to an embodiment of the present disclosure. FIG. 21B is a top-down view of a region of the exemplary structure of FIG. 21A. FIG. 21C is a magnified view of a region C in FIG. 21A.

FIG. 22A is a vertical cross-sectional view of a region of the exemplary structure after performing a first selective isotropic etch process that etches sacrificial plates according to an embodiment of the present disclosure. FIG. 22B is a top-down view of a region of the exemplary structure of FIG. 22A. FIG. 22C is a magnified view of a region C in FIG. 22A.

FIG. 23A is a vertical cross-sectional view of a region of the exemplary structure after performing a second selective isotropic etch process that etches proximal portions of the sacrificial lateral isolation trench fill structures around laterally-extending voids to form inter-tier voids according to an embodiment of the present disclosure. FIG. 23B is a top-down view of a region of the exemplary structure of FIG. 23A. FIG. 23C is a magnified view of a region C in FIG. 23A.

FIG. 24A is a vertical cross-sectional view of a region of the exemplary structure after performing a third selective isotropic etch process that etches proximal portions of the sacrificial material layers around inter-tier voids according to an embodiment of the present disclosure. FIG. 24B is a top-down view of a region of the exemplary structure of FIG. 24A. FIG. 24C is a magnified view of a region C in FIG. 24A.

FIG. 25A is a vertical cross-sectional view of a region of the exemplary structure after performing a fourth selective isotropic etch process that etches the material of the insulating layers according to an embodiment of the present disclosure. FIG. 25B is a top-down view of a region of the exemplary structure of FIG. 25A. FIG. 25C is a magnified view of a region C in FIG. 25A.

FIG. 26 is a vertical cross-sectional view of a region of the exemplary structure after formation of support pillar structures according to an embodiment of the present disclosure.

FIG. 27 is a vertical cross-sectional view of a region of the exemplary structure after formation of inter-tier contact openings according to an embodiment of the present disclosure.

FIG. 28 is a vertical cross-sectional view of a region of the exemplary structure after formation of contact via structures according to an embodiment of the present disclosure.

FIG. 29A is a vertical cross-sectional view of a region of the exemplary structure after formation of slit-shaped openings according to an embodiment of the present disclosure. FIG. 29B is a top-down view of a region of the exemplary structure of FIG. 29A.

FIG. 30 is a vertical cross-sectional view of a region of the exemplary structure after formation of voids in the lateral isolation trenches according to an embodiment of the present disclosure.

FIG. 31 is a vertical cross-sectional view of a region of the exemplary structure after formation of laterally-extending cavities by removal of sacrificial material layers according to an embodiment of the present disclosure.

FIG. 32 is a vertical cross-sectional view of a region of the exemplary structure after formation of electrically conductive layers according to an embodiment of the present disclosure.

FIG. 33A is a vertical cross-sectional view of a region of the exemplary structure after formation of lateral isolation trench fill structures according to an embodiment of the present disclosure. FIG. 33B is a top-down view of a region of the exemplary structure of FIG. 33A. FIG. 33C is a magnified view of region C in FIG. 33A. FIG. 33D is a magnified view of region D in FIG. 33A. FIG. 33E is a magnified view of region E of FIG. 33A.

FIG. 34 is a vertical cross-sectional view of the exemplary structure after formation of additional openings according to an embodiment of the present disclosure.

FIG. 35A is a vertical cross-sectional view of a region of the exemplary structure after formation of drain contact via structures according to an embodiment of the present disclosure. FIG. 35B is a top-down view of a region of the exemplary structure of FIG. 35A. FIG. 35C is a magnified view of region C in FIG. 35A. FIG. 35D is a magnified view of region D in FIG. 35A. FIG. 35E is a magnified view of region E of FIG. 35A. FIG. 35F is a horizontal cross-sectional view of the exemplary structure of FIG. 35A along horizontal plane F-F′. FIGS. 35G, 35H and 35I are horizontal cross-sectional views of alternative embodiments of the exemplary structure of FIG. 35A along horizontal plane F-F′.

### DETAILED DESCRIPTION

Embodiments of the disclosure can be employed to form semiconductor devices, such as three-dimensional memory devices employing localized lateral isolation trench widening and methods for forming the same.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

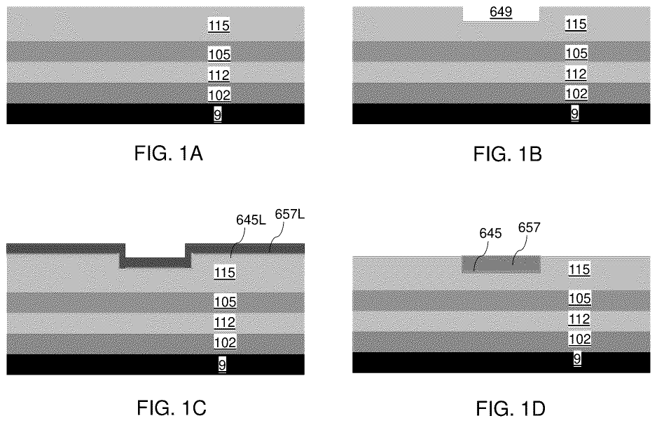

FIGS. 1A-1D are sequential vertical cross-sectional views of a region of an exemplary structure during formation of source-level material layers (102, 112, 105, 115) and source-select-level sacrificial plates 657 according to an embodiment of the present disclosure.

Referring to FIG. 1A, the first exemplary structure comprises a substrate 9, which may be a semiconductor substrate. For example, the substrate 9 may be a commercially available single crystalline silicon wafer. Source-level material layers (102, 112, 105, 115) can be formed on a top surface of the substrate 9. The source-level material layers (102, 112, 105, 115) may comprise, from bottom to top, a first source isolation layer 102, a semiconductor source layer 112, a second source isolation layer 105, and a source-select-level electrode layer 115. The first source isolation layer 102 and the second source isolation layer 105 comprise a dielectric material, such as silicon oxide, and may have respective thickness in a range from 30 nm to 300 nm, although lesser and greater thicknesses may also be employed. The semiconductor source layer 112 comprises a heavily doped semiconductor material, such as polysilicon, having a doping of an opposite conductivity type relative to the conductivity type of vertical semiconductor channels to be subsequently formed. For example, if the vertical semiconductor channels to be subsequently formed have a doping of a first conductivity type, the semiconductor source layer 112 has a doping of a second conductivity type that is the opposite of the first conductivity type. The thickness of the semiconductor source layer 112 may be in a range from 60 nm to 600 nm, although lesser or greater thicknesses may also be employed. The source-select-level electrode layer 115 comprises a conductive material, such as a heavily doped semiconductor material, such as polysilicon. The thickness of the source-select-level electrode layer 115 may be in a range from 100 nm to 400 nm, although lesser or greater thicknesses may also be employed.

Referring to FIG. 1B, a photoresist layer (not shown) can be applied over the source-select-level electrode layer 115, and can be lithographically patterned to form arrays of openings therein. The pattern of the arrays of openings may be the same as the pattern of first sacrificial plates and second sacrificial plates to be formed in upper levels in subsequent processing steps described below. An etch process can be performed to transfer the pattern of the openings in the photoresist layer into an upper portion of the source-select-level electrode layer 115. Source-select-level recess cavities 649 are formed in the upper portion of the source-select-level electrode layer 115. The depth of the source-select-level recess cavities 649 may be in a range from 50 nm to 200 nm, although lesser or greater depths may also be employed. The photoresist layer can be subsequently removed, for example, by ashing.

Referring to FIG. 1C, a dielectric liner layer 645L and a source-select-level sacrificial fill material layer 657L can be sequentially deposited. The dielectric liner layer 645L comprises a dielectric material, such as silicon oxide, and may have a thickness in a range from 10 nm to 50 nm, although lesser or greater thicknesses may also be employed. The source-select-level sacrificial fill material layer 657L comprises a sacrificial fill material, such as silicon nitride.

Referring to FIG. 1D excess portions of the source-select-level sacrificial fill material layer 657L and the dielectric liner layer 645L can be removed from above the horizontal plane including the top surface of the source-select-level electrode layer 115 by performing a planarization process, such as a chemical mechanical polishing process. Remaining portions of the dielectric liner layer 645L constitute dielectric liners 645. Remaining portions of the source-select-level sacrificial fill material layer 657L constitute source-select-level sacrificial plates 657.

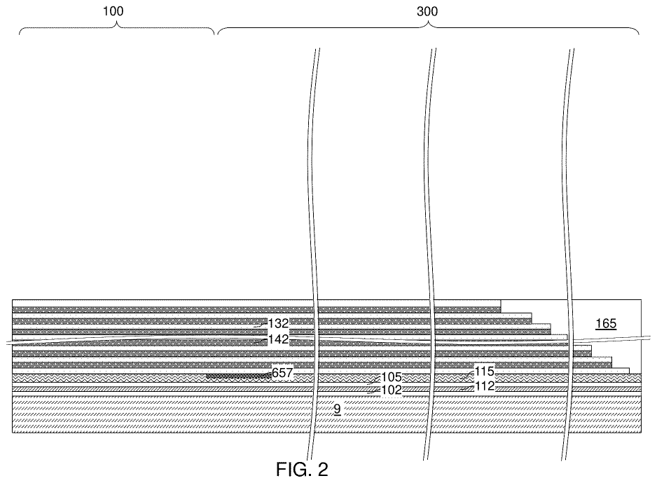

Referring to FIG. 2, a first-tier alternating stack of first-tier insulating layers 132 and first sacrificial material layers 142 can be formed over the source-level material layers (102, 112, 105, 115). The first-tier insulating layers 132 comprise an insulating material, such as undoped silicate glass (i.e., silicon oxide) or a doped silicate glass, and the first sacrificial material layers 142 comprise a sacrificial material, such as silicon nitride or a silicon-germanium alloy. In one embodiment, the first-tier insulating layers 132 may comprise silicon oxide layers, and the first sacrificial material layers 142 may comprise silicon nitride layers. The first-tier alternating stack (132, 142) may comprise multiple repetitions of a unit layer stack including a first-tier insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed.

Each of the first-tier insulating layers 132 may have a thickness in a range from 10 nm to 60 nm, such as from 15 nm to 40 nm, although lesser and greater thicknesses may also be employed. Each of the first sacrificial material layers 142 may have a thickness in a range from 15 nm to 70 nm, such as from 20 nm to 50 nm, although lesser and greater thicknesses may also be employed.

The exemplary structure comprises a memory array region 100 in which a three-dimensional array of memory elements is to be subsequently formed, and a contact (i.e., staircase) region 300 in which stepped surfaces of the alternating stack and layer contact via structures contacting electrically conductive layers (e.g., word lines and select gate electrodes) are to be subsequently formed.

First stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first-tier alternating stack (132, 142) are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first-tier alternating stack (132, 142) laterally extends farther than any overlying first sacrificial material layer 142 within the first-tier alternating stack (132, 142) in the terrace region. Generally, the first stepped surfaces continuously extend from a bottommost layer within the first-tier alternating stack (132, 142) at least to a topmost layer within the first-tier alternating stack (132, 142).

A first retro-stepped dielectric material portion 165 (i.e., an insulating fill material portion) can be formed in the first stepped cavity by deposition of a dielectric material therein. For example, a dielectric material such as silicon oxide can be deposited in the first stepped cavity. Excess portions of the deposited dielectric material can be removed from above the top surface of the first-tier alternating stack (132, 142), for example, by chemical mechanical polishing (CMP) process. The remaining portion of the deposited dielectric material filling the first stepped cavity constitutes the first retro-stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first retro-stepped dielectric material portion 165, the silicon oxide of the first retro-stepped dielectric material portion 165 may, or may not, be doped with dopants such as B, P, and/or F.

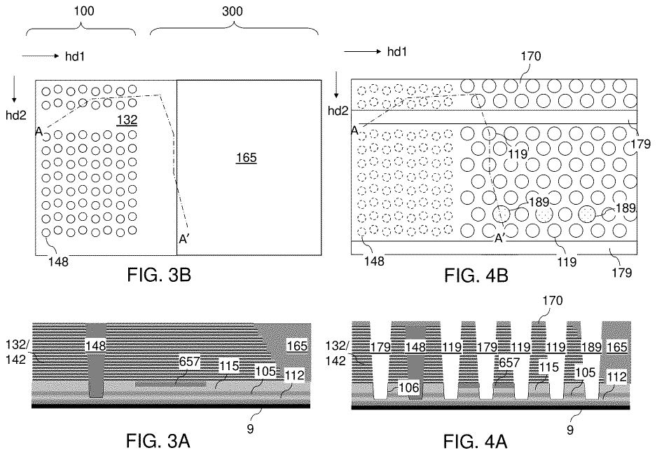

Referring to FIGS. 3A and 3B, an etch mask layer (not shown) can be formed over the first-tier alternating stack (132, 142) and the first retro-stepped dielectric material portion 165. The etch mask layer may comprise a carbon-based material, such as a carbon-based patterning film as known in the art. A photoresist layer (not shown) can be formed above the etch mask layer, and can be lithographically patterned to form various openings therein. A first anisotropic etch process can be performed to transfer the pattern of the openings in the photoresist layer through the first etch mask layer, the first-tier alternating stack (132, 142), and the first retro-stepped dielectric material portion 165. The photoresist layer and an upper portion of the etch mask layer can be collaterally removed during the first anisotropic etch process. Remaining portions of the etch mask layer can be removed after the first anisotropic etch process, for example, by ashing.

First-tier memory openings are formed in the memory array region 100. In one embodiment, the memory array region 100 may be laterally spaced apart from the contact region 300 along the first horizontal direction hd1. The first-tier memory openings may comprise rows of first-tier memory openings that are arranged along the first horizontal direction hd1 (e.g., word line direction) and laterally spaced apart along the second horizontal direction hd2 (e.g., bit line direction). Multiple clusters (e.g., memory block areas) of first-tier memory openings, each containing a respective two-dimensional periodic array of first-tier memory openings, may be formed in the memory array region 100. The clusters of first-tier memory openings may be laterally spaced apart along the second horizontal direction hd2. The first-tier memory openings may have a diameter in a range from 50 nm to 400 nm, such as from 70 nm to 300 nm, although lesser and greater diameters may be employed.

A first sacrificial memory opening fill material can be deposited in the first-tier memory openings. The first sacrificial memory opening fill material may comprise a carbon-based material, such as amorphous carbon or diamond-like carbon. A planarization process can be performed to remove portions of the first sacrificial memory opening fill material from above the horizontal plane including the top surface of the first-tier alternating stack (132, 142). Remaining portions of the first sacrificial fill material that fill the first-tier memory openings constitute first-tier sacrificial memory opening fill material portions 148.

Referring to FIGS. 4A and 4B, a first-tier insulating cap layer 170 can be formed over the first-tier alternating stack (132, 142) and the first retro-stepped dielectric material portion 165. The first-tier insulating cap layer 170 comprises an insulating material, such as silicon oxide, and may have a thickness in a range from 60 nm to 300 nm, such as from 100 nm to 200 nm, although lesser or greater thicknesses may also be employed.

An etch mask layer (not shown) can be formed over the first-tier insulating cap layer 170. The etch mask layer may comprise a carbon-based material, such as a carbon-based patterning film as known in the art. A photoresist layer (not shown) can be formed above the etch mask layer, and can be lithographically patterned to form various openings therein. An anisotropic etch process can be performed to transfer the pattern of the openings in the photoresist layer through the etch mask layer, the first-tier insulating cap layer 170, the first-tier alternating stack (132, 142), and the first retro-stepped dielectric material portion 165. The photoresist layer and an upper portion of the first etch mask layer can be collaterally removed during the anisotropic etch process. Remaining portions of the etch mask layer can be removed after the anisotropic etch process, for example, by ashing.

The various openings may comprise first-tier support openings 119 that are formed in the contact region 300, first-tier contact openings 189 that are formed in the contact region 300, and first-tier lateral isolation trenches 179 that laterally extend along the first horizontal direction hd1 across the memory array region 100 and the contact region 300. Each of the first-tier support openings 119 and the first-tier lateral isolation trenches 179 can vertically extend through the first-tier insulating cap layer 170, the first-tier alternating stack (132, 142) into an upper portion of the semiconductor source layer 112.

The first-tier support openings 119 may have a diameter in a range from 50 nm to 400 nm, such as from 70 nm to 300 nm, although lesser and greater diameters may be employed. The first-tier lateral isolation trenches 179 may have a width in a range from 150 nm to 1,000 nm, such as from 200 nm to 600 nm, although lesser and greater widths may also be employed. The first-tier support openings 119 and the first-tier contact openings 189 may comprise discrete openings. The first-tier lateral isolation trenches 179 may laterally extend along a first horizontal direction hd1 with a uniform width along a second horizontal direction (e.g., bit line direction) hd2 that is perpendicular to the first horizontal direction hd1.

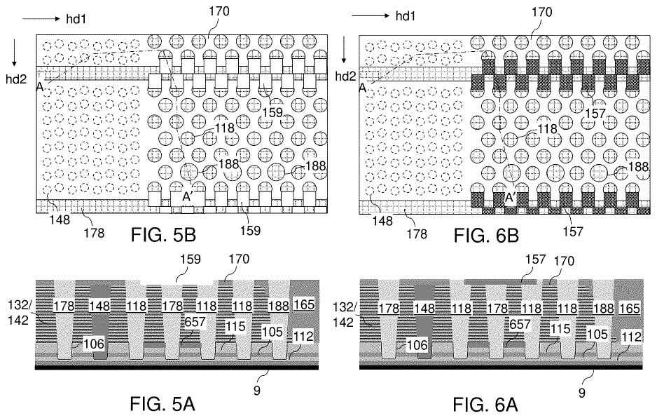

Referring to FIGS. 5A and 5B, an etch-stop liner 106 and a first sacrificial fill material can be formed in the first-tier support openings 119, the first-tier contact openings 189, and the first-tier lateral isolation trenches 179. The etch-stop liner 106 comprises a thin silicon oxide layer having a thickness in a range from 1 nm to 6 nm. In one embodiment, the etch-stop liner 106 may be formed by oxidizing physically exposed surface portions of the semiconductor source layer 112 and the source-select-level electrode layer 115. The first sacrificial fill material may comprise a semiconductor material, such as amorphous silicon or polysilicon.

A planarization process can be performed to remove portions of the first sacrificial fill material from above the horizontal plane including the top surface of the first-tier insulating cap layer 170. Remaining portions of the first sacrificial fill material that fill the first-tier support openings 119, the first-tier contact openings 189, and the first-tier lateral isolation trenches 179 constitute first-tier sacrificial opening fill material portions (118, 188, 178). The first-tier sacrificial opening fill material portions (118, 188, 178) comprise first-tier sacrificial support opening fill material portions 118 that are formed in the first-tier support openings 119, first-tier sacrificial contact opening fill material portions 188 that are formed in the first-tier contact openings 189, and first-tier sacrificial lateral isolation trench fill material portions 178 that are formed in the first-tier lateral isolation trenches 179.

A photoresist layer (not shown) can be applied over the first-tier insulating cap layer 170, and can be lithographically patterned to form arrays of openings therein. The pattern of the arrays of openings may be the same as the pattern of source-select-level recess cavities 649 described above. In one embodiment, the arrays of openings may comprise rows of openings arranged along the first horizontal direction hd1. Each opening may have an areal overlap in a plan view with a peripheral region of a respective first-tier sacrificial support opening fill material portion 118 and with a region of a respective first-tier sacrificial lateral isolation trench fill material portion 178.

An etch process can be performed to transfer the pattern of the openings in the photoresist layer into an upper portion of the first-tier insulating cap layer 170. First-tier cap-level recess cavities 159 are formed in the upper portion of the first-tier insulating cap layer 170. The depth of the first-tier cap-level recess cavities 159 may be less than the thickness of the first-tier insulating cap layer 170, and may be in a range from 50 nm to 200 nm, although lesser or greater depths may also be employed. The photoresist layer can be subsequently removed, for example, by ashing.

A sacrificial fill material can be deposited in the first-tier cap-level recess cavities 159 to form first sacrificial plates 157. The sacrificial fill material of the first sacrificial plates 157 comprises a material that can be subsequently removed selectively to the material of the first-tier insulating cap layer 170. In one embodiment, the first sacrificial plates 157 may comprise the same material as the source-select-level sacrificial plates 657. Top surfaces of the first sacrificial plates 157 can be formed within the horizontal plane including the top surface of the first-tier insulating cap layer 170. Optionally, a dielectric liner layer, such as a silicon oxide liner layer similar to the previously described dielectric liner layer 645L may be formed in the first-tier cap-level recess cavities 159 below the first sacrificial plates 157.

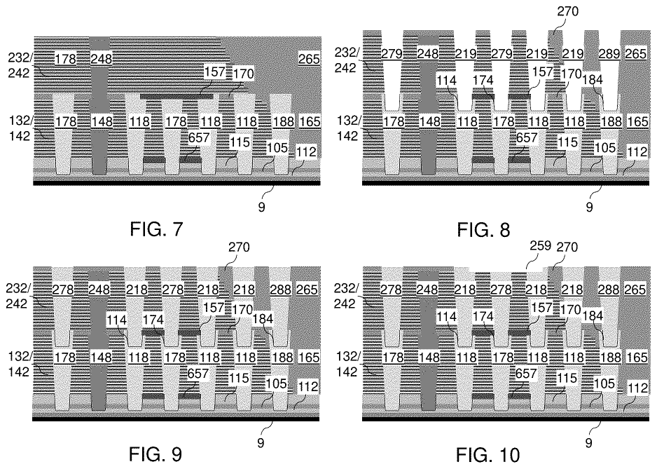

Referring to FIG. 7, the processing steps described with reference to FIGS. 2, 3A, and 3B may be performed with any needed changes to form a second-tier alternating stack of second-tier insulating layers 232 and second sacrificial material layers 242, second stepped surfaces, a second retro-stepped dielectric material portion 265, and second-tier memory openings. The second stepped surfaces may be laterally offset relative to the first stepped surfaces toward the memory array region 100. A top surface of a first-tier sacrificial memory opening fill material portion 148 can be physically exposed underneath each second-tier memory opening. A second sacrificial memory opening fill material can be deposited in the second-tier memory openings to form second-tier sacrificial memory opening fill material portions 248. The second-tier sacrificial memory opening fill material portions 248 may have the same pattern and the same material as the first-tier sacrificial memory opening fill material portions 148.

Referring to FIG. 8, the processing steps described with reference to FIGS. 4A and 4B may be performed with any needed changes to form a second-tier insulating cap layer 270, second-tier support openings 219, second-tier contact openings 289, and second-tier lateral isolation trenches 279. Each of the second-tier support openings 219 and the second-tier lateral isolation trenches 279 can vertically extend through the second-tier insulating cap layer 270 and the second-tier alternating stack (232, 242). The second-tier support openings 219 are formed on first-tier sacrificial support opening fill material portions 118. The second-tier contact openings 289 are formed on the first-tier sacrificial contact opening fill material portions 188. The second-tier lateral isolation trenches 279 are formed on the first-tier sacrificial lateral isolation trench fill material portions 178.

An etch-stop liner (174, 114, 184) can be formed on the physically exposed surfaces of the first-tier sacrificial opening fill material portions (178, 118, 188), for example, by oxidation of surface portions of the semiconductor sacrificial material of the first-tier sacrificial opening fill material portions (178, 118, 188). If the semiconductor sacrificial material comprises silicon (e.g., amorphous silicon or polysilicon), then the etch-stop liner (174, 114, 184) comprises silicon oxide. A first isolation-trench etch-stop liner 174 can be formed on each first-tier sacrificial lateral isolation trench fill material portion 178. A first support-opening etch-stop liner 114 can be formed on each first-tier sacrificial support opening fill material portion 118. A first contact-opening etch-stop liner 184 can be formed on each first-tier sacrificial contact opening fill material portion 188.

Referring to FIG. 9, the processing steps described with reference to FIG. 5 can be performed with any needed changes to form various second-tier sacrificial fill material portions (278, 218, 118). The various second-tier sacrificial fill material portions (278, 218, 118) comprise a second sacrificial fill material, which may be the same as the first sacrificial fill material. The second-tier sacrificial opening fill material portions (218, 288, 278) comprise second-tier sacrificial support opening fill material portions 218 that are formed in the second-tier support openings 219, second-tier sacrificial contact opening fill material portions 288 that are formed in the second-tier contact openings 289, and optional second-tier sacrificial lateral isolation trench fill material portions 278 that are formed in the second-tier lateral isolation trenches 279.

Referring to FIG. 10, a photoresist layer (not shown) can be applied over the second-tier insulating cap layer 270, and can be lithographically patterned to form arrays of openings therein. The pattern of the arrays of openings may be the same as the pattern of source-select-level recess cavities 649 and the pattern of the first-tier cap-level recess cavities 159 described above. Thus, each opening may have an areal overlap in a plan view with a peripheral region of a respective second-tier sacrificial support opening fill material portion 218 and with a region of a respective second-tier sacrificial lateral isolation trench fill material portion 278.

An etch process can be performed to transfer the pattern of the openings in the photoresist layer into an upper portion of the second-tier insulating cap layer 270. Second-tier cap-level recess cavities 259 are formed in the upper portion of the second-tier insulating cap layer 270. The depth of the second-tier cap-level recess cavities 259 may be less than the thickness of the second-tier insulating cap layer 270, and may be in a range from 50 nm to 200 nm, although lesser or greater depths may also be employed. The photoresist layer can be subsequently removed, for example, by ashing.

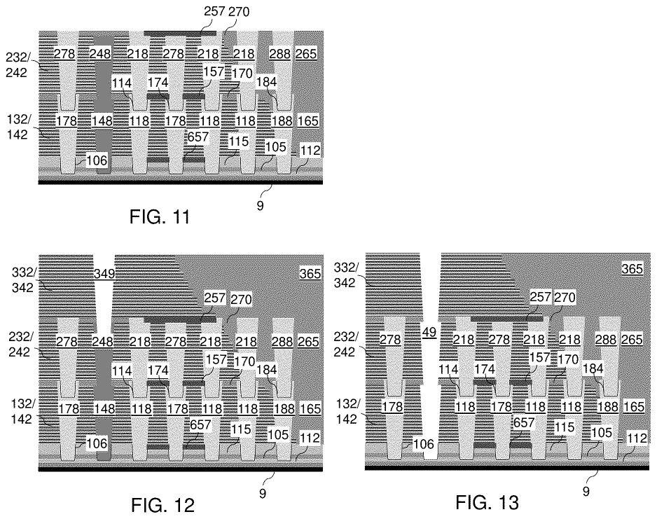

Referring to FIG. 11, a sacrificial fill material can be deposited in the second-tier cap-level recess cavities 259 to form second sacrificial plates 257. The sacrificial fill material of the second sacrificial plates 257 comprises a material that can be subsequently removed selectively to the material of the second-tier insulating cap layer 270. In one embodiment, the second sacrificial plates 257 may comprise the same material as the source-select-level sacrificial plates 657 and the first sacrificial plates 157. Top surfaces of the second sacrificial plates 257 can be formed within the horizontal plane including the top surface of the second-tier insulating cap layer 270. Optionally, a dielectric liner layer, such as a silicon oxide liner layer similar to the previously described dielectric liner layer 645L may be formed in the second-tier cap-level recess cavities 159 below the first sacrificial plates 257.

Referring to FIG. 12, the processing steps described with reference to FIGS. 2, 3A, and 3B may be performed with any needed changes to form a third-tier alternating stack of third-tier insulating layers 332 and third sacrificial material layers 342, third stepped surfaces, a third retro-stepped dielectric material portion 365, and third-tier memory openings 349 can be formed. The third stepped surfaces may be laterally offset relative to the second stepped surfaces toward the memory array region 100. A top surface of a second-tier sacrificial memory opening fill material portion 248 can be physically exposed underneath each third-tier memory opening.

Referring to FIG. 13, the sacrificial fill materials of the second-tier sacrificial memory opening fill material portions 248 and the first-tier sacrificial memory opening fill material portions 148 can be removed through the third-tier memory openings 349 selectively to the materials of the alternating stacks (132, 142, 232, 242, 332, 342), the insulating cap layers (170, 270), and the retro-stepped dielectric material portions (165, 265, 365). For example, if the sacrificial fill materials of the second-tier sacrificial memory opening fill material portions 248 and the first-tier sacrificial memory opening fill material portions 148 comprise carbon-based materials, an ashing process may be employed to remove the sacrificial fill materials of the second-tier sacrificial memory opening fill material portions 248 and the first-tier sacrificial memory opening fill material portions 148. An inter-tier memory opening 49, which is also referred to as a memory opening 49, is formed within each continuous vertically extending volume that includes a volume of a third-tier memory opening 349, a volume of the second-tier memory opening 249 formed by removal of a second-tier sacrificial memory opening fill material portions 248, and a volume of the first-tier memory opening 149 formed by removal of a first-tier sacrificial memory opening fill material portion 148.

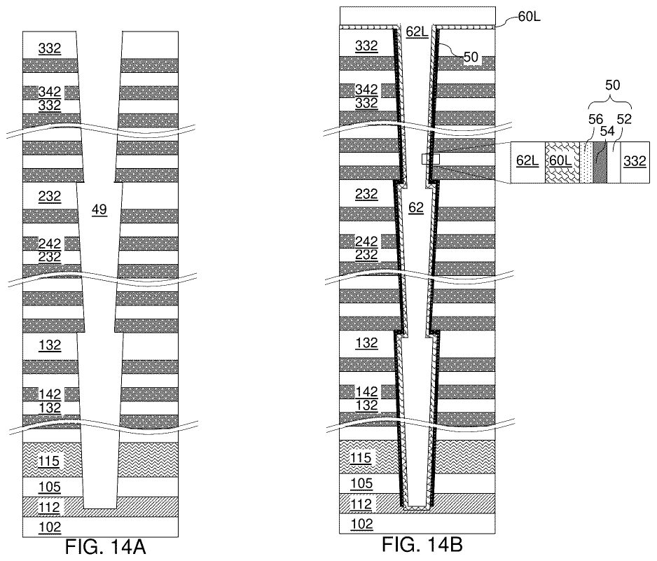

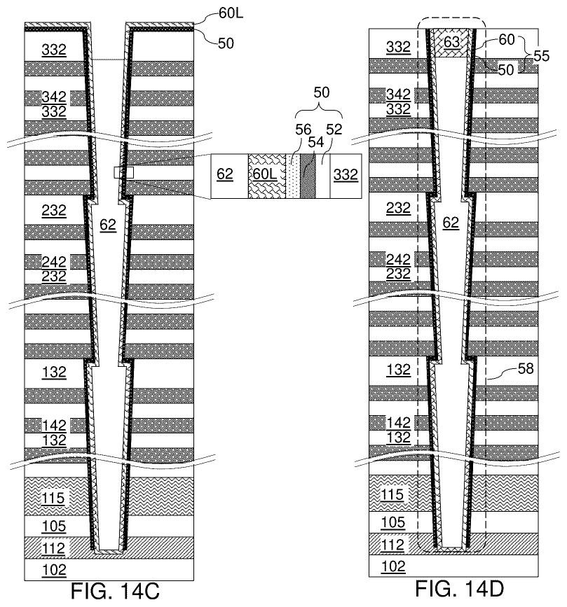

FIGS. 14A-14D are sequential vertical cross-sectional views of a region around an inter-tier memory opening during formation of a memory opening fill structure 58 according to an embodiment of the present disclosure.

Referring to FIG. 14A, a memory opening 49 is illustrated after the processing steps of FIG. 13.

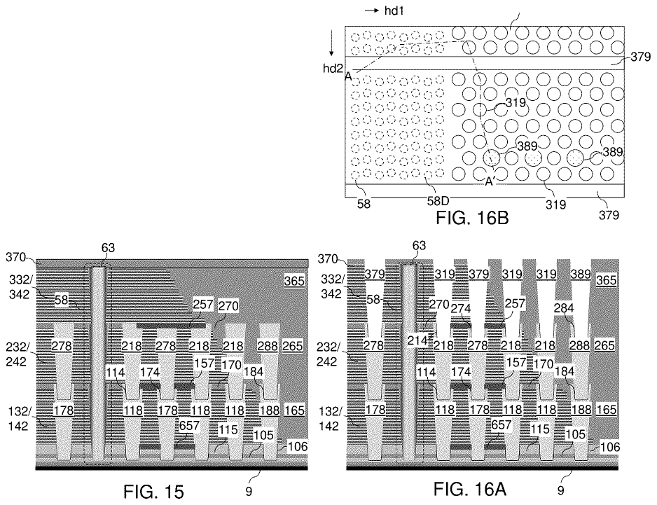

Referring to FIG. 15B, a memory film 50 including a memory material layer 54 can be conformally deposited. In an illustrative example, the memory film 50 may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

An anisotropic etch process can be performed to remove horizontally-extending portions of the memory film 50. A surface of a semiconductor source layer 112 can be physically exposed at the bottom of each memory opening 49. A semiconductor channel material layer 60L can be deposited over the memory film 50 on the physically exposed surface segments of the semiconductor source layer 112 by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the semiconductor channel material layer 60L.

Referring to FIG. 14C, the dielectric core layer 62L can be vertically recessed such that each remaining portion of the dielectric core layer 62L has a top surface at, or about, the horizontal plane including the bottom surface of the topmost third-tier insulating layer 332. Each remaining portion of the dielectric core layer 62L constitutes a dielectric core 62.

Referring to FIG. 14D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost third-tier insulating layer 332, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers (142, 242, 342).

Referring to FIG. 15, a third-tier insulating cap layer 370 can be formed over the third-tier alternating stack (332, 342) and the third retro-stepped dielectric material portion 365. The third-tier insulating cap layer 370 comprises an insulating material, such as silicon oxide, and has a thickness in a range from 100 nm to 400 nm, although lesser or greater thicknesses may also be employed.

Referring to FIGS. 16A and 16B, the processing steps described with reference to FIGS. 4A and 4B may be performed with any needed changes to form third-tier support openings 319, third-tier contact openings 389, and third-tier lateral isolation trenches 379. Each of the third-tier support openings 319 and the third-tier lateral isolation trenches 379 can vertically extend through the third-tier insulating cap layer 370 and the third-tier alternating stack (232, 342). The third-tier support openings 319 are formed on second-tier sacrificial support opening fill material portions 218. The third-tier contact openings 389 are formed on the second-tier sacrificial contact opening fill material portions 288. The third-tier lateral isolation trenches 379 are formed on the second-tier sacrificial lateral isolation trench fill material portions 278.

An etch-stop liner (274, 214, 284) can be formed on the physically exposed surfaces of the second-tier sacrificial opening fill material portions (278, 218, 288), for example, by oxidation of surface portions of the sacrificial material of the second-tier sacrificial opening fill material portions (278, 218, 288). The etch stop liners may comprise silicon oxide formed by oxidation of silicon sacrificial material. A second isolation-trench etch-stop liner 274 can be formed on each second-tier sacrificial lateral isolation trench fill material portion 278. A second support-opening etch-stop liner 214 can be formed on each second-tier sacrificial support opening fill material portion 218. A second contact-opening etch-stop liner 284 can be formed on each second-tier sacrificial contact opening fill material portion 288.

Referring to FIG. 16B, some of the memory opening fill structures 58 may comprise dummy memory opening fill structures 58D. The dummy opening memory fill structures 58D may have the same structure as the active memory opening fill structures 58, but are not used to store data. For example, the drain regions 63 of the dummy memory opening fill structures 58D may be electrically unconnected to bit lines. The dummy memory opening fill structures 58D may be located on an end of the memory array region 100 between the active memory opening fill structures 58 and the contact region 300.

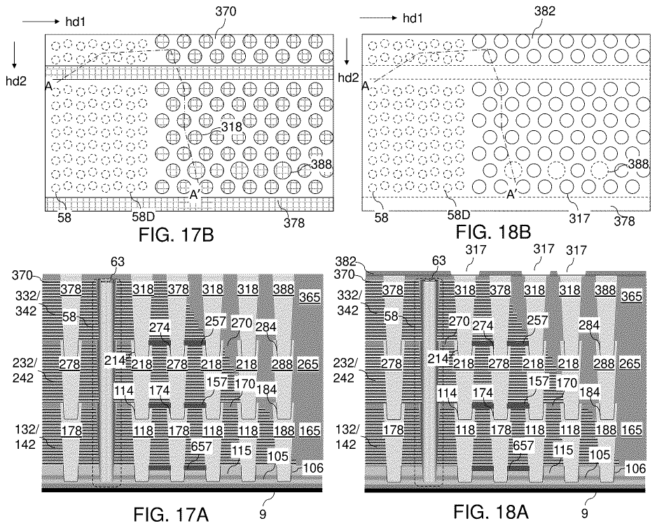

Referring to FIGS. 17A and 17B, the processing steps described with reference to FIG. 5 can be performed with any needed changes to form various third-tier sacrificial fill material portions (278, 318, 218). The various third-tier sacrificial fill material portions (278, 318, 218) comprise a third sacrificial fill material, which may be the same as the second sacrificial fill material. The sacrificial opening fill material portions (218, 388, 378) comprise third-tier sacrificial support opening fill material portions 318 that are formed in the third-tier support openings 319, third-tier sacrificial contact opening fill material portions 388 that are formed in the third-tier contact openings 389, and optional third-tier sacrificial lateral isolation trench fill material portions 378 that are formed in the third-tier lateral isolation trenches 379.

Sacrificial lateral isolation trench fill structures (178, 278, 378, 106, 174, 274) are formed in the isolation trenches. Each sacrificial lateral isolation trench fill structures (178, 278, 378, 106, 174, 274) comprises a vertical stack of a first-tier sacrificial lateral isolation trench fill material portions 178, a second-tier sacrificial lateral isolation trench fill material portions 278, and a third-tier sacrificial lateral isolation trench fill material portions 378 and etch-stop liners (106, 174, 274). Each sacrificial lateral isolation trench fill structure (178, 278, 378, 106, 174, 274) laterally extends along the first horizontal direction hd1.

Referring to FIGS. 18A and 18B, a first contact-level dielectric layer 382 can be formed over the third-tier insulating cap layer 370. The first contact-level dielectric layer 382 comprises an insulating material such as silicon oxide, and may have a thickness in a range from 100 nm to 400 nm, although lesser or greater thicknesses may also be employed.

A photoresist layer (not shown) can be applied over the first contact-level dielectric layer 382, and can be lithographically patterned to form arrays of openings in areas that overlap with the areas of the third-tier sacrificial support opening fill material portions 318. An etch process can be performed to transfer the pattern of the openings in the photoresist layer through the first contact-level dielectric layer 382. Through-holes 317 are formed through the first contact-level dielectric layer 382 over the third-tier sacrificial support opening fill material portions 318. The photoresist layer can be subsequently removed, for example, by ashing.

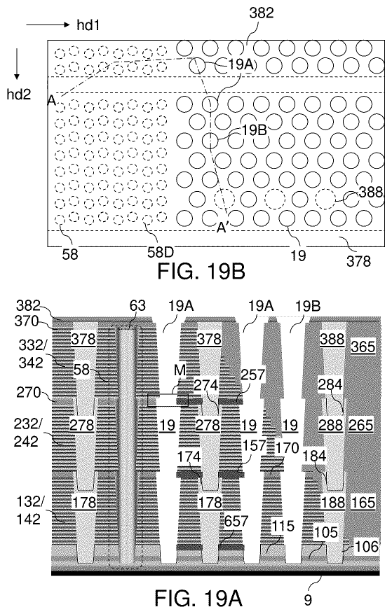

Referring to FIGS. 19A and 19B, sacrificial fill materials of the third-tier sacrificial support opening fill material portions 318, second-tier sacrificial support opening fill material portions 218, and first-tier support opening fill material portions 118 can be removed selectively to the materials of the alternating stacks (132, 142, 232, 242, 332, 342), the insulating cap layers (170, 270, 370), the retro-stepped dielectric material portions (165, 265, 365), and the first contact-level dielectric layer 382. Inter-tier support openings 19, wherein are also referred to as support openings 19, are formed in the volumes from which the materials of the third-tier sacrificial support opening fill material portions 318, second-tier sacrificial support opening fill material portions 218, and first-tier support opening fill material portions 118 are removed.

Generally, the support openings 19 may comprise a first subset of support openings 19A that are exposed to the source-select-level sacrificial plates 657, the first sacrificial plates 157, and the second sacrificial plates 257, and a second subset of support openings 19B that are not exposed to the source-select-level sacrificial plates 657, the first sacrificial plates 157, and the second sacrificial plates 257. In other words, each support opening 19A in the first subset of the support openings 19 exposes a surface of a respective source-select-level sacrificial plate 657, a surface of a respective first sacrificial plate 157, and a surface of a respective second sacrificial plate 257 as surface segments of the respective support opening 19A. Each support opening 19B in the second subset of the support openings 19 is laterally spaced from and is not exposed to any of the source-select-level sacrificial plates 657, the first sacrificial plates 157, and the second sacrificial plates 257.

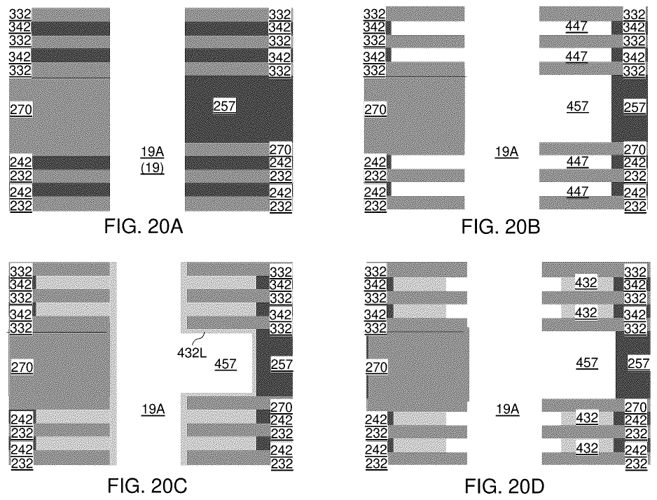

FIGS. 20A-20D are sequential vertical cross-sectional views of region M of the exemplary structure illustrated in FIG. 19A during formation of insulating fins 432 according to an embodiment of the present disclosure.

Referring to FIG. 20A, a portion of a support opening 19A is illustrated around region M of the exemplary structure of FIG. 19A. The support opening 19A is one of support openings 19 in the first subset of the support openings 19A. As such, a surface of a source-select-level sacrificial plate 657, a surface of a first sacrificial plate 157, and a surface of a second sacrificial plate 257 are physically exposed to the support opening 19A.

Referring to FIG. 20B, a selective isotropic etch process can be performed to laterally recess the physically exposed surfaces of the source-select-level sacrificial plates 657, the first sacrificial plates 157, and the second sacrificial plates 257. Physically exposed surfaces of the sacrificial material layers (142, 242, 342) may be collaterally recessed during the selective isotropic etch process. In one embodiment, the source-select-level sacrificial plates 657, the first sacrificial plates 157, and the second sacrificial plates 257 and the sacrificial material layers (142, 242, 342) comprise silicon nitride, and the selective isotropic etch process may comprise a wet etch process employing hot phosphoric acid. Layer-level fin cavities 447 are formed in volume from which portions of the sacrificial material layers (142, 242, 342) are removed, and cap-level cavities 457 are formed in volumes from which portions of the source-select-level sacrificial plates 657, the first sacrificial plates 157, and the second sacrificial plates 257 are removed.

Referring to FIG. 20C, an insulating fill material layer 432L can be conformally deposited in peripheral regions of the support openings 19, in peripheral regions of the cap-level cavities 457, and in the entire volume of each of the layer-level fin cavities 447. The insulating fill material layer 432L includes an insulating material such as a doped silicate glass or an undoped silicate glass (i.e., silicon oxide). The insulating fill material layer 432L can be deposited by a conformal deposition process, such as a low pressure chemical vapor deposition process. The thickness of the insulating fill material layer 432L is greater than one half of the height of each layer-level fin cavity 447, and is less than one half of the height of the cap-level cavities 457. The entire volume of each layer-level fin cavity 447 is filled with a respective portion of the insulating fill material layer 432L, while only peripheral regions of the cap-level cavities 457 are filled within portions of the insulating fill material layer 432L.

Referring to FIG. 20D, an isotropic etch process can be performed to isotropically etch the material of the insulating fill material layer 432L. The etch distance of the isotropic etch process can be greater than the thickness of the insulating fill material layer 432L as deposited at the processing steps of FIG. 20C. Each remaining portion of the insulating fill material layer 432L filling a respective one of the layer-level fin cavities 447 constitutes an insulating fin 432. Sidewalls of the source-select-level sacrificial plates 657, the first sacrificial plates 157, and the second sacrificial plates 257 are physically exposed. Sidewalls of the sacrificial material layers (142, 242, 342) around each support opening 19 are covered by the insulating fins 432.

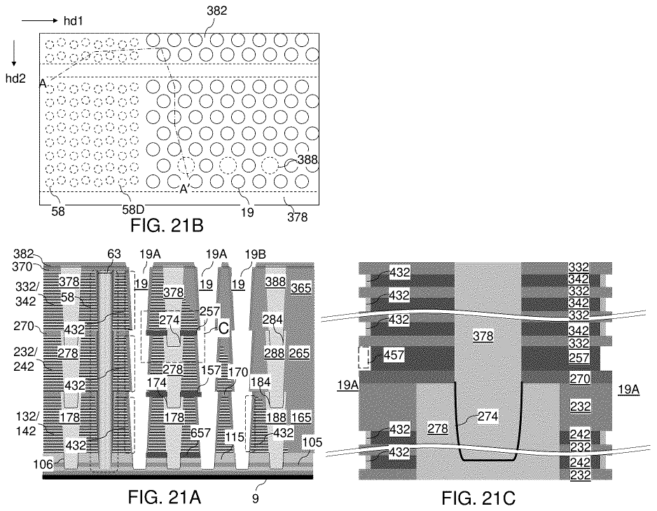

Referring to FIGS. 21A-21C , the exemplary structure is illustrated after formation of insulating fins 432 around the support openings 19. Surfaces of the source-select-level sacrificial plates 657, the first sacrificial plates 157, and the second sacrificial plates 257 are physically exposed around the first subset of the support openings 19. Surfaces of the source-select-level sacrificial plates 657, the first sacrificial plates 157, and the second sacrificial plates 257 are not physically exposed to the second subset of the support openings 19. Each support opening 19A in the first subset of the support openings 19 is located proximal to a respective sacrificial lateral isolation trench fill structure (178, 278, 378, 106, 174, 274).

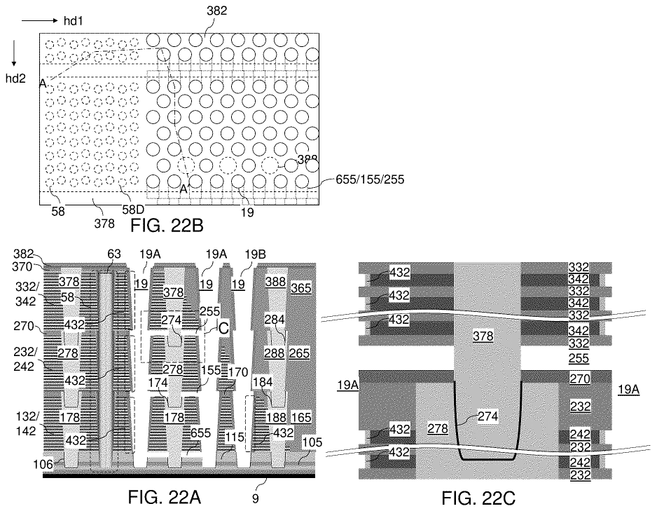

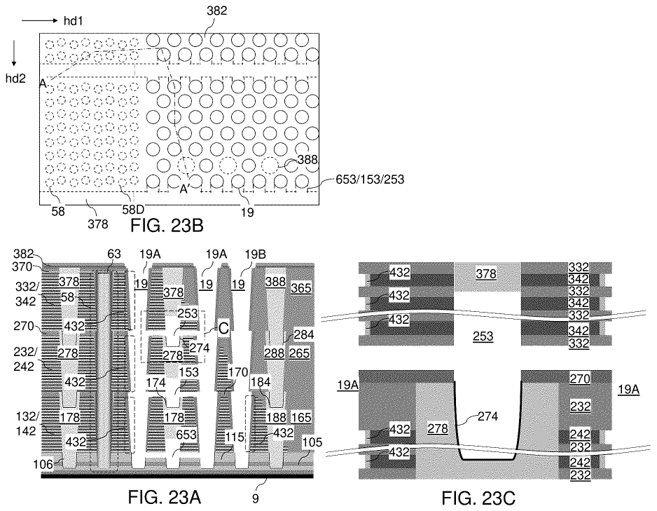

Referring to FIGS. 22A-22C , a first selective isotropic etch process can be performed to etch the sacrificial plates (657, 157, 257) without etching the materials of the alternating stacks (132, 232, 232, 242, 332, 342), the insulating cap layers (170, 270, 370), the retro-stepped dielectric material portions (165, 265, 365), and the insulating fins 432. The first selective isotropic etch process may be selective to the materials of the sacrificial lateral isolation trench fill structures (178, 278, 378, 106, 174, 274). For example, if the sacrificial plates (657, 157, 257) comprise silicon nitride, the first selective isotropic etch process may comprise a wet etch process employing hot phosphoric acid. Laterally-extending voids (655, 155, 255) are formed in the volumes from which the materials of the sacrificial plates (657, 157, 257) are removed through the cap-level cavities 457 and the support openings 19A. In contrast, the silicon nitride sacrificial material layers (142, 242, 342) are protected from being etched by the silicon oxide insulating fins 432. Source-select-level laterally-extending voids 655 are formed in the volumes from which source-select-level sacrificial plates 657 are removed. First laterally-extending voids 155 are formed in the volumes from which the first sacrificial plates 157 are removed. Second laterally-extending voids 255 are formed in the volumes from which the second sacrificial plates 257 are removed. Sidewall surface segments of the sacrificial lateral isolation trench fill structures (178, 278, 378, 106, 174, 274) are exposed in the support openings 19A around the various laterally-extending voids (655, 155, 255).

Referring to FIGS. 23A-23C, a second selective isotropic etch process can be performed to selectively etch proximal portions of the sacrificial lateral isolation trench fill structures (178, 278, 378, 106, 174, 274) without etching the materials of the alternating stacks (132, 232, 232, 242, 332, 342), the insulating cap layers (170, 270, 370), the retro-stepped dielectric material portions (165, 265, 365), and the insulating fins 432. The etch-stop liners (e.g., silicon oxide liners) (174, 184, 274, 284, 106) function as etch stop layers during the second selective isotropic etch process. For example, if the sacrificial lateral isolation trench fill structures (178, 278, 378, 106, 174, 274) comprise a semiconductor material such as polysilicon, the second selective isotropic etch process may comprise a wet etch process employing tetramethylammonium hydroxide (TMAH) or trimethyl-2 hydroxyethyl ammonium hydroxide (TMY).

The second selective isotropic etch process etches proximal portions of the sacrificial lateral isolation trench fill structures (178, 278, 378, 106, 174, 274) around the laterally-extending voids (655, 155, 255) to form inter-tier voids (653, 153, 253). The inter-tier voids (653, 153, 253) comprise select-electrode-level voids 653 that are formed in volumes from which segments of the first-tier sacrificial lateral isolation trench fill material portions 178 are removed; first-cap-level voids 153 that are formed in volumes from which segments of the second-tier sacrificial lateral isolation trench fill material portions 278 are removed; and second-cap-level voids 253 that are formed in volumes from which segments of the third-tier sacrificial lateral isolation trench fill material portions 378 are removed. Sidewalls of a lower subset of the first-tier alternating stacks (132, 142) are exposed around the select-electrode-level voids 653. Sidewalls of a lower subset of the first-tier alternating stacks (232, 242) are physically exposed around the first-cap-level voids 153. Sidewalls of a lower subset of the second-tier alternating stacks (332, 342) are physically exposed around the second-cap-level voids 253.

In one embodiment, the sacrificial lateral isolation trench fill material portions (178, 278, 378) may comprise polysilicon, and the etch-stop liners (106, 174, 274) may comprise silicon oxide. In this case, the etch-stop liners (106, 174, 274) prevent etching of upper portions of the first-tier sacrificial lateral isolation trench fill material portion 178 and the second-tier sacrificial lateral isolation trench fill material portion 278 during the second selective isotropic etch process.

The total number of levels of first sacrificial material layers 142 that are exposed to each select-electrode-level void 653 may be in a range from 3% to 60%, such as from 6% to 30%, of the total number of levels of the first sacrificial material layers 142 in the first-tier alternating stacks (132, 142). The total number of levels of second sacrificial material layers 242 that are exposed to each first-cap-level void 153 may be in a range from 3% to 60%, such as from 6% to 30%, of the total number of levels of the second sacrificial material layers 242 in the second-tier alternating stacks (232, 242). The total number of levels of third sacrificial material layers 342 that are exposed to each second-cap-level void 253 may be in a range from 3% to 60%, such as from 6% to 30%, of the total number of levels of the third sacrificial material layers 342 in the third-tier alternating stacks (332, 342).

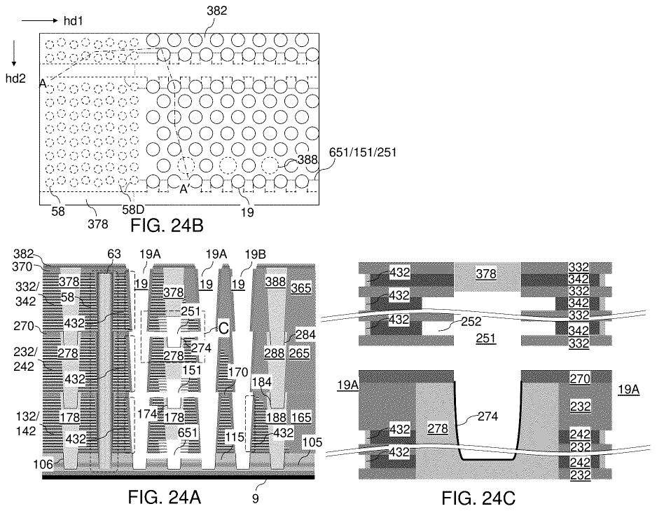

Referring to FIGS. 24A-24C, a third selective isotropic etch process can be performed to etch portions of the sacrificial material layers (142, 242, 342) that are proximal to the select-electrode-level voids 653, the first-cap-level voids 153, and the second-cap-level voids 253 selective to the materials of the insulating layers (132, 232, 332), the insulating cap layers (170, 270, 370), the insulating fins 432, and the etch-stop dielectric liners (174, 184, 274, 284, 106). For example, if the sacrificial material layers (142, 242, 342) comprise silicon nitride, the third selective isotropic etch process may comprise a wet etch process employing hot phosphoric acid. The third selective isotropic etch process etches proximal portions of the sacrificial material layers (142, 242, 342) around the inter-tier voids (653, 153, 253) to form fin-shaped voids 252. Each contiguous combination of an inter-tier void (653, 153, 253) and fin-shaped voids 252 comprises a finned void (651, 151, 251). The finned voids (651, 151, 251) comprise select-electrode-level finned voids 651 that are formed in volumes from which segments of the first-tier sacrificial lateral isolation trench fill material portions 178 and first sacrificial material layers 142 are removed; first finned voids 151 that are formed in volumes from which segments of the second-tier sacrificial lateral isolation trench fill material portions 278 and second sacrificial material layers 242 are removed; and second finned voids 251 that are formed in volumes from which segments of the third-tier sacrificial lateral isolation trench fill material portions 378 and third sacrificial material layers 342 are removed.

The total number of levels of first sacrificial material layers 142 that are exposed to each select-electrode-level finned void 651 may be in a range from 3% to 60%, such as from 6% to 30%, of the total number of levels of the first sacrificial material layers 142 in the first-tier alternating stacks (132, 142). The total number of levels of second sacrificial material layers 242 that are exposed to each first finned void 151 may be in a range from 3% to 60%, such as from 6% to 30%, of the total number of levels of the second sacrificial material layers 242 in the second-tier alternating stacks (232, 242). The total number of levels of third sacrificial material layers 342 that are exposed to each second finned void 251 may be in a range from 3% to 60%, such as from 6% to 30%, of the total number of levels of the third sacrificial material layers 342 in the third-tier alternating stacks (332, 342).

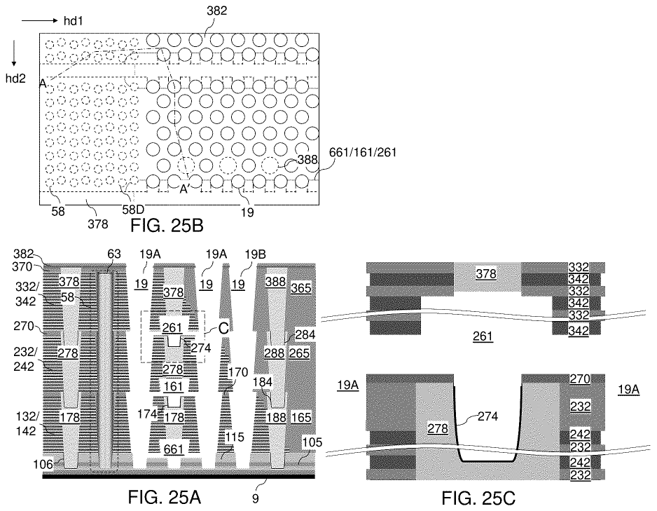

Referring to FIGS. 25A-25C, a fourth selective isotropic etch process can be performed to selectively isotropically etch the material of the insulating layers (132, 232, 332). The insulating fins 432 may be collaterally etched during the fourth selective isotropic etch process. Generally, the etch distance of the fourth selective isotropic etch process for the material of the insulating layers (132, 232, 332) is greater than one half of the thickness of each insulating layer (132, 232, 332). Thus, the fin-shaped cavities of the finned voids (661, 161, 261) are expanded and merge with each other during the fourth selective isotropic etch process. Further, the duration of the fourth selective isotropic etch process may be selected such that the insulating fins 432 are removed during the fourth selective isotropic etch process.

The lateral isolation trenches 79 are selectively widened only at the levels of the lower portions of the first-tier alternating stacks (132, 142), the levels of the lower portions of the second-tier alternating stacks (232, 242), and the levels of the lower portions of the third-tier alternating stacks (332, 342) without widening portions of the lateral isolation trenches 79 at the levels of the upper portions of the first-tier alternating stacks (132, 142), the levels of the upper portions of the second-tier alternating stacks (232, 242), and the levels of the upper portions of the third-tier alternating stacks (332, 342). In-trench voids (661, 161, 261) are formed within the sacrificial lateral isolation trench fill structures (178, 278, 378, 106, 174, 274). The in-trench voids (661, 161, 261) comprise source-select-level in-trench voids 661 that underlie a respective one of the first-tier sacrificial lateral isolation trench fill material portions 178, first in-trench voids 161 that underlie a respective one of the second-tier sacrificial lateral isolation trench fill material portions 278, and second in-trench voids 261 that underlie a respective one of the third-tier sacrificial lateral isolation trench fill material portions 378. Each of the in-trench voids (661, 161, 261) can be connected to a respective pair of rows of support openings 19A through a respective set of two rows of laterally-extending connection voids.

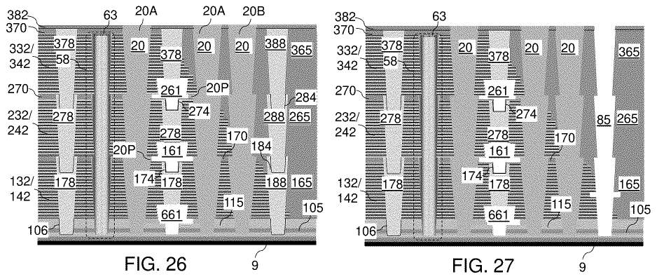

Referring to FIG. 26, an anisotropic deposition process can be employed to anisotropically deposit a dielectric fill material, such as undoped silicate glass (e.g., silicon oxide) or a doped silicate glass. For example, the anisotropic deposition process may comprise a plasma-enhanced chemical vapor deposition (PECVD) process. The anisotropic nature of the deposition process employed to deposit the dielectric fill material minimizes filling of the laterally-extending connection voids, and prevents filling of the in-trench voids (661, 161, 261) by the deposited dielectric fill material.

Excess portions of the deposited dielectric fill material can be removed from above the horizontal plane including the top surface of the first contact-level dielectric layers 382 by performing a planarization process, such as a recess etch process and/or a chemical mechanical polishing process. Each remaining portion of the deposited dielectric fill material that fills a respective one of the support openings 19 constitutes a support pillar structure 20. A first subset of the support pillar structures 20A that is formed in the first subset of the support openings 19 that are connected to the laterally-extending connection voids may comprise a respective laterally-protruding portion 20P that protrudes into a respective one of the laterally-extending connection voids. A second subset of the support pillar structures 20B that is formed in the second subset of the support openings 19 that are not connected to any of the laterally-extending connection voids may be free of any lateral protrusions.

Referring to FIG. 27, openings can be formed through the first contact-level dielectric layer 382 over the areas of the third-tier sacrificial contact opening fill material portions 388. A selective etch process can be performed to etch the materials of the third-tier sacrificial contact opening fill material portions 388, the second-tier sacrificial contact opening fill material portions 288, and the third-tier sacrificial contact opening fill material portions 388 selectively to the materials of the first contact-level dielectric layer 382, the alternating stacks (132, 142, 232, 242, 332, 342), and the retro-stepped dielectric material portions (165, 265, 365). For example, if the sacrificial contact opening fill material portions (388, 288, 188) comprise a semiconductor material, a wet etch process employing tetramethylammonium hydroxide (TMAH) or trimethyl-2 hydroxyethyl ammonium hydroxide (TMY) may be employed.

Contact via cavities 85 can be formed in the volumes from which the materials of the third-tier sacrificial contact opening fill material portions 388, the second-tier sacrificial contact opening fill material portions 288, and the third-tier sacrificial contact opening fill material portions 388 are removed. Portions of the sacrificial material layers (142, 242, 342) may then be selectively removed around the contact via cavities 85 only around contact regions in which layer contact via structures will contact electrically conductive layers in subsequent processing steps.

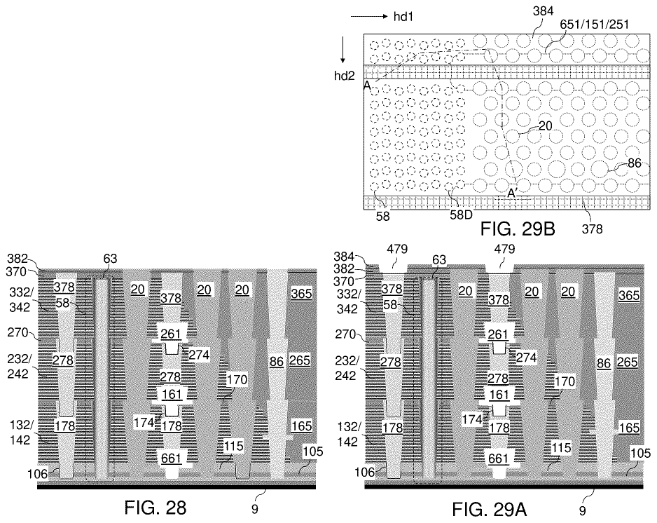

Referring to FIG. 28, contact via fill structures 86 can be formed in the contact via cavities 85 by depositing an electrically conductive fill material in each of the contact via cavities 85. The electrically conductive fill material may comprise a metal, such as tungsten, and an optional diffusion barrier layer, such as Ti, TiN, WN, TaN or MoN.

Referring to FIGS. 29A and 29B, a second contact-level dielectric layer 384 can be deposited over the first contact-level dielectric layer 382. The second contact-level dielectric layer 384 comprises a dielectric material, such as silicon oxide, and may have a thickness in a range from 50 nm to 400 nm, although lesser and greater thicknesses may also be employed.

A photoresist layer (not shown) can be applied over the second contact-level dielectric layer 384, and can be lithographically patterned to form slit-shaped openings having shapes of the sacrificial lateral isolation trench fill structures (178, 278, 378, 106, 174, 274, 661, 161, 261). An etch process can be performed to form slit-shaped openings 479 through the second contact-level dielectric layer 384. Top surfaces of the sacrificial lateral isolation trench fill structures (178, 278, 378, 106, 174, 274, 661, 161, 261) are exposed underneath the slit-shaped openings 479.

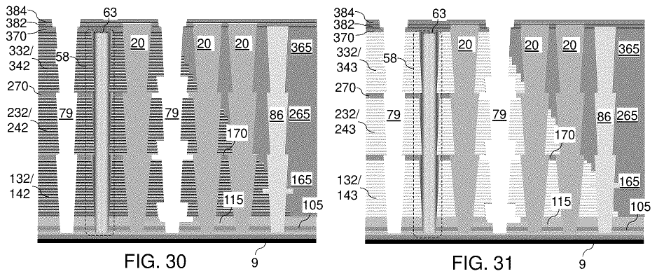

Referring to FIG. 30, the solid material portions (178, 278, 378, 106, 174, 274) of the sacrificial lateral isolation trench fill structures are removed by performing at least one etch process. The at least one etch process may comprise a set of anisotropic etch processes that sequentially etches the third-tier sacrificial support opening fill material portions 318, the second isolation-trench etch-stop liners 274, the second-tier sacrificial support opening fill material portions 218, the first isolation-trench etch-stop liners 174, and the first-tier sacrificial support opening fill material portions 118 to reopen the lateral isolation trenches 79. Each of the lateral isolation trenches 79 may have a variable width (i.e., a width-modulated) vertical cross-sectional profile in a vertical cross-sectional view perpendicular to the first horizontal direction hd1. Generally, the degree of local widening of the lateral isolation trenches 79 at lower levels of each alternating stack {(132, 142), (232, 242), or (332, 242)} can be selected such that each lateral isolation trench 79 has a relatively uniform overall width, and excessive narrowing of the lateral isolation trenches 79 at the lower levels of each alternating stack {(132, 142), (232, 242), or (332, 242)} is avoided.

Referring to FIG. 31, an isotropic etch process can be performed to remove the sacrificial material layers (142, 242, 342) through the lateral isolation trenches 79 selectively to the insulating layers (132, 232, 332), the contact-level dielectric layers (382, 384), the memory opening fill structures 58, the support pillar structures 20, and the retro-stepped dielectric material portions (165, 265, 365). The isotropic etch process employs an isotropic etchant that etches materials of the sacrificial material layers (142, 242, 342) selective to the materials of the insulating layers (132, 232, 332), the contact-level dielectric layers (382, 384), the memory opening fill structures 58, the support pillar structures 20, and the retro-stepped dielectric material portions (165, 265, 365). In an illustrative example, the insulating layers (132, 232, 332) may comprise silicon oxide, and the sacrificial material layers (142, 242, 342) may comprise silicon nitride. In this case, the isotropic etch process may comprise a wet etch process employing hot phosphoric acid. Laterally-extending cavities (143, 243, 343) can be formed between each neighboring pair of lateral isolation trenches 79. The laterally-extending cavities (143, 243, 343) can be formed in volumes from which the sacrificial material layers (142, 242, 342) are removed. Sidewall surface segments of the memory opening fill structures 58 can be physically exposed to the laterally-extending cavities (143, 243, 343).

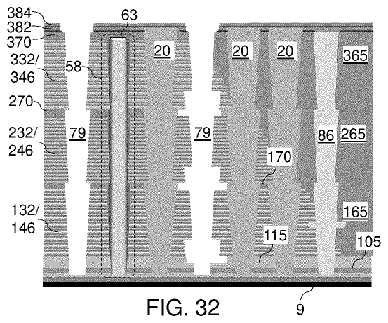

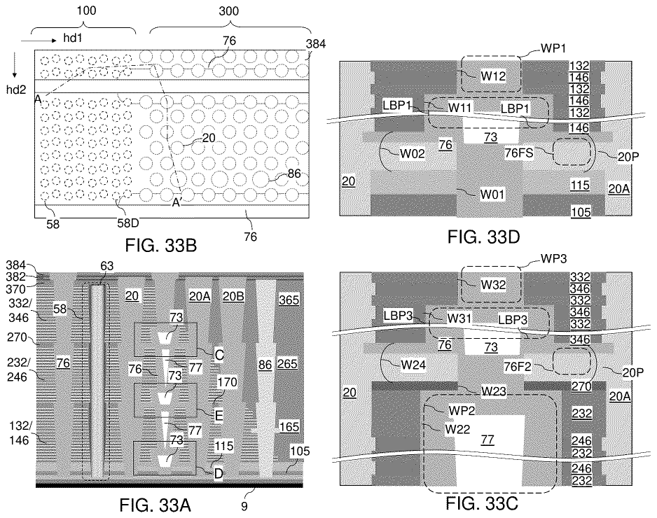

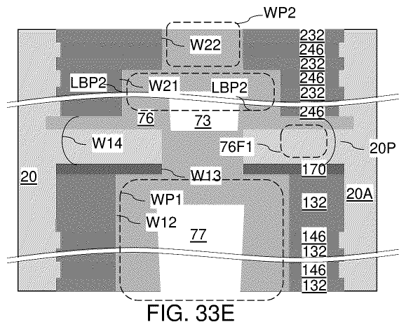

Referring to FIG. 32, an optional outer blocking dielectric layer (not illustrated) can be conformally deposited in peripheral portions of the laterally-extending cavities (143, 243, 343). At least one conductive material can be conformally deposited in remaining unfilled volumes of the laterally-extending cavities (143, 243, 343). The at least one conductive material may comprise, for example, a combination of a metallic barrier material and a metal fill material. The metallic barrier material may comprise, for example, TiN, TaN, WN, MoN, TiC, TaC, WC, or a combination thereof. The metal fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layers (382, 384) can be removed by performing an etch-back process, which may comprise an isotropic etch process and/or an anisotropic etch process. Generally, all portions of the at least one conductive material deposited outside the laterally-extending cavities (143, 243, 343) are removed by an isotropic recess etch process. Each remaining portion of the at least one conductive material filling a respective one of the laterally-extending cavities (143, 243, 343) constitutes an electrically conductive layer (146, 246, 346).

The electrically conductive layers (146, 246, 346) comprise first-tier electrically conductive layers 146 that are interlaced with the first-tier insulating layers 132, second-tier electrically conductive layers 246 that are interlaced with the second-tier insulating layers 232, and third-tier electrically conductive layers 346 that are interlaced with the third-tier insulating layers 332. A first-tier alternating stack of first-tier insulating layers 132 and first-tier electrically conductive layers 146 is formed between each neighboring pair of lateral isolation trenches 79 and between a respective first-tier insulating cap layer 170 and the source-select-level electrode layer 115. A second-tier alternating stack of second-tier insulating layers 232 and second-tier electrically conductive layers 246 is formed between each neighboring pair of lateral isolation trenches 79 and between a respective second-tier insulating cap layer 270 and a respective first-tier insulating cap layer 170. A third-tier alternating stack of third-tier insulating layers 332 and second-tier electrically conductive layers 346 is formed between each neighboring pair of lateral isolation trenches 79 and between a respective third-tier insulating cap layer 370 and a respective second-tier insulating cap layer 270. Each of the layer contact via structures 86 contacts a respective one of the electrically conductive layers (146, 246, 346). The first-tier sacrificial material layers 142, the second-tier sacrificial material layers 242, and the third-tier sacrificial material layers 342 are replaced with first-tier electrically conductive layers 146, second-tier electrically conductive layers 246, and third-tier electrically conductive layers 346, respectively.

Referring to FIGS. 33A-33E, a dielectric fill material, such as undoped silicate glass or a doped silicate glass, can be conformally deposited in the volumes of the lateral isolation trenches 79, to form lateral isolation trench fill structures 76 which include various protrusions along the second horizontal direction hd2 at various levels.

As shown in FIG. 33D, each lateral isolation trench fill structure 76 comprises a pair of rows of source-electrode-level dielectric fins 76FS overlying the source-select-level electrode layer 115 and laterally protruding along the second horizontal direction hd2 toward a respective one of the support pillar structures 20, a first laterally-bulging portion LBP1 between lower portions of a neighboring pair of first-tier alternating stacks (132, 146), and a first-tier wall portion WP1 located between upper portions of the neighboring pair of first-tier alternating stacks (132, 146). As shown in FIG. 33E, each lateral isolation trench fill structure 76 also comprises a pair of rows of first-cap-level dielectric fins 76F1 located between a neighboring pair of first-tier insulating cap layers 170 and laterally protruding along the second horizontal direction hd2 toward a respective one of the support pillar structures 20, a second laterally-bulging portion LBP2 between lower portions of a neighboring pair of second-tier alternating stacks (232, 246), and a second tier wall portion WP2 located between upper portions of the neighboring pair of second-tier alternating stacks (232, 246). As shown in FIG. 33C, each lateral isolation trench fill structure 76 also comprises a pair of rows of second-cap-level dielectric fins 76F2 located between a neighboring pair of second-tier insulating cap layers 270 and laterally protruding along the second horizontal direction hd2 toward a respective one of the support pillar structures 20, a third laterally-bulging portion LBP3 between lower portions of a neighboring pair of third-tier alternating stacks (333, 346), and a third tier wall portion WP3 located between upper portions of the neighboring pair of third-tier alternating stacks (333, 346).

In one embodiment, each first laterally-bulging portion LBP1 laterally protrudes along the second horizontal direction hd2 with respect to an overlying first-tier wall portion WP1 of the lateral isolation trench fill structure 76, each second laterally-bulging portion LBP2 laterally protrudes along the second horizontal direction hd2 with respect to an overlying second-tier wall portion WP2 of the lateral isolation trench fill structure 76, and each third laterally-bulging portion LBP3 laterally protrudes along the second horizontal direction hd2 with respect to an overlying third-tier wall portion WP3 of the lateral isolation trench fill structure 76, as shown in FIGS. 33D, 33E and 33C, respectively.

In one embodiment, each of the vertical layer stacks (132, 146, 170, 232, 246, 270, 332, 346, 370) comprises a respective contact region 300 in which lateral extents of the vertical layer stacks (132, 146, 170, 232, 246, 270, 332, 346, 370) along the first horizontal direction hd1 vary (e.g., decrease) with an upward distance from a horizontal plane including bottommost surfaces of the pair of vertical layer stacks (132, 146, 170, 232, 246, 270, 332, 346, 370).

Within each lateral isolation trench fill structure 76, the first-tier wall portion WP1 is located between the first laterally-bulging portion LBP1 and the second laterally-bulging portion LBP2, and the second-tier wall portion WP2 is located between the second laterally-bulging portion LBP2 and the third laterally-bulging portion LBP3, and the third-tier wall portion WP3 overlies the third laterally-bulging portion LBP3.

In one embodiment, each lateral isolation trench fill structure 76 comprises a pair of contoured lengthwise sidewalls that generally extend along the first horizontal direction hd1 with lateral modulations along the second horizontal direction hd2. As shown in FIG. 33D, each of the pair of contoured lengthwise sidewalls comprises, from bottom to top, a respective first source-select-level sidewall segment W01 contacting a sidewalls of the source-select-level electrode layer 115, respective second source-select-level sidewall segments W02 contacting a respective one of the support pillar structures 20, a respective first-tier lower lengthwise sidewall segment W11 that is a sidewall of the first laterally-bulging portion LBP1, a respective first first-tier horizontal connecting surface that is adjoined to a top edge of the respective first-tier lower lengthwise sidewall segment W11, and a respective first-tier upper lengthwise sidewall segment W12 that is a sidewall of the first-tier wall portion WP1 and has a bottom edge that adjoins an inner edge of the respective first first-tier horizontal connecting surface.

As shown in FIG. 33E, each of the pair of contoured lengthwise sidewalls further comprises, from bottom to top, a respective second first-tier horizontal connecting surface that is adjoined to a top edge of the respective first-tier upper lengthwise sidewall segment W12, a respective first-tier insulating cap layer sidewall segment W13 that is adjoined to an inner edge of the respective second first-tier horizontal connecting surface, a respective third first-tier horizontal connecting surface that is a horizontal surface segment of the first-tier insulating cap layer 170, and respective topmost first-tier surface segments W14 that contact the support pillar structures 20, a respective second-tier lower lengthwise sidewall segment W21 that is a sidewall of the second laterally-bulging portion LBP2, and a respective first second-tier horizontal connecting surface that is adjoined to a top edge of the respective second-tier lower lengthwise sidewall segment W21,

As shown in FIG. 33C, each of the pair of contoured lengthwise sidewalls further comprises, from bottom to top, a respective second-tier upper lengthwise sidewall segment W22 that is a sidewall of the second-tier wall portion WP2 and has a bottom edge that adjoins an inner edge of the respective first second-tier horizontal connecting surface, a respective second second-tier horizontal connecting surface that is adjoined to a top edge of the respective second-tier upper lengthwise sidewall segment W22, a respective second-tier insulating cap layer sidewall segment W23 that is adjoined to an inner edge of the respective second second-tier horizontal connecting surface, a respective third second-tier horizontal connecting surface that is a horizontal surface segment of the second-tier insulating cap layer 270, and respective topmost second-tier surface segments W24 that contact the support pillar structures 20. In addition, each of the pair of contoured lengthwise sidewalls comprises, from bottom to top, a respective third-tier lower lengthwise sidewall segment W31 that is a sidewall of the third laterally-bulging portion LBP3, a respective first third-tier horizontal connecting surface that is adjoined to a top edge of the respective third-tier lower lengthwise sidewall segment W31, and a respective third-tier upper lengthwise sidewall segment W32 that is a sidewall of the third-tier wall portion WP3 and has a bottom edge that adjoins an inner edge of the respective first third-tier horizontal connecting surface.

In one embodiment, each first first-tier horizontal connecting surface is a bottom surface of a respective one of the first-tier insulating layers 132, each first second-tier horizontal connecting surface is a bottom surface of a respective one of the second-tier insulating layers 232, and each first third-tier horizontal connecting surface is a bottom surface of a respective one of the third-tier insulating layers 332.

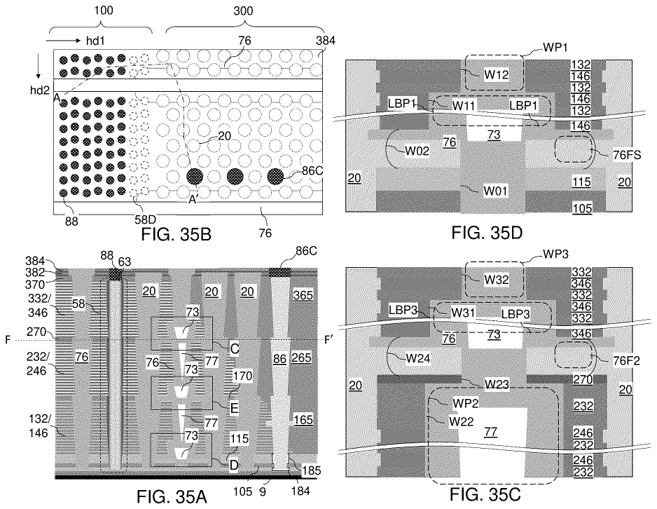

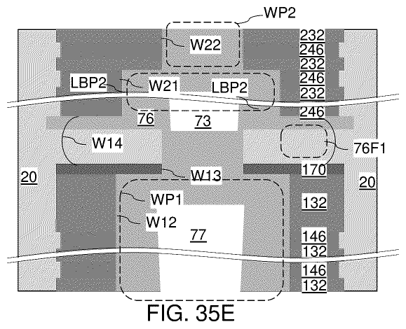

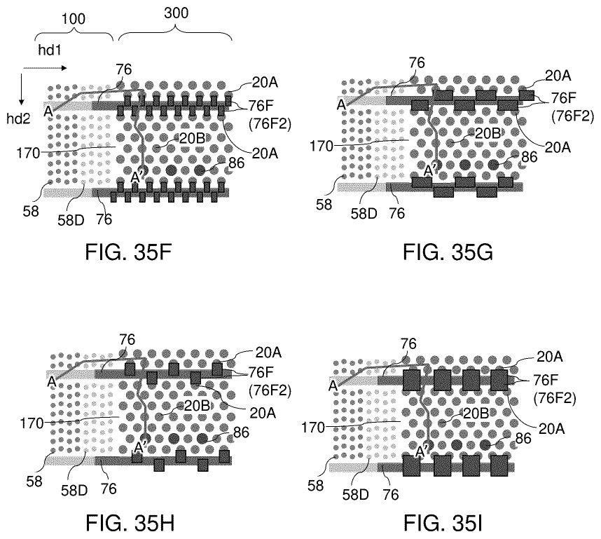

In one embodiment shown in FIG. 35A, sidewalls of the first-tier wall portion WP1 have a respective taper angle in a vertical cross-sectional view in a vertical plane that is perpendicular to the first horizontal direction hd1. A width of a bottom portion of the second-tier wall portion WP2 along the second horizontal direction hd2 is less than a width of a top portion of the first-tier wall portion WP1 along the second horizontal direction hd2.

In one embodiment shown in FIG. 33E, top surfaces of the first-tier-cap-level fins 76F1 are located within a horizontal plane including top surfaces of the first-tier insulating cap layers 170; and bottom surfaces of the first-tier-cap-level fins 76F1 are located within a horizontal plane including recessed horizontal surfaces of the first-tier insulating cap layers 170. In one embodiment, the first-tier-cap-level fins 76F1 underlie the second laterally-bulging portion LBP2 and laterally protrude along the second horizontal direction hd2 from sidewalls of the second laterally-bulging portion LBP2.

Support pillar structures 20 vertically extend through a respective one of the vertical layer stacks (132, 146, 170, 232, 246, 270, 332, 346, 370). A first subset of the support pillar structures 20A comprises a respective laterally-protruding fin portion 20P located at a level of the first-tier insulating cap layers 170 and contacting a respective one of the first-tier-cap-level fins 76F1; and a second subset of the support pillar structures 20B is free of any laterally-protruding fin portion. In one embodiment, the laterally-protruding fin portions 20P of the first subset of the support pillar structures 20 has a same vertical thickness as the first-tier-cap-level fins 76F1 of the lateral isolation trench fill structure 76.

As shown in FIG. 33E, a lateral spacing between neighboring pairs of first-tier insulating cap layers 170 is less than a width of the second laterally-bulging portion LBP2 of the lateral isolation trench fill structure 76. As shown in FIG. 33C, a lateral spacing between neighboring pairs of second-tier insulating cap layers 270 is less than a width of the third laterally-bulging portion LBP3 of the lateral isolation trench fill structure 76.

In one embodiment, each lateral isolation trench fill structure 76 may comprise first encapsulated voids (i.e., air gaps) 73 that are encapsulated by a respective one of the laterally-bulging portions (LBP1, LBP2, LBP3) and second encapsulated voids (e.g., air gaps) 77 that are encapsulated by a respective one of the first-tier wall portion WP1 and the second-tier wall portion WP2.

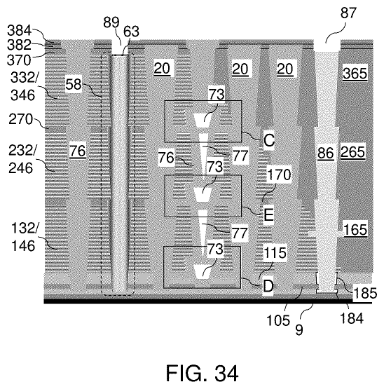

Referring to FIG. 34, drain contact via cavities 89 and layer contact via cavities 87 are formed through the dielectric layers to expose the drain regions and the contact via fill structures 86. The drain contact via cavities 89 are formed through the contact-level dielectric layers (382, 384) and the third-tier insulating cap layer 370.

Referring to FIGS. 35A-35I , electrically conductive drain contact via structures 88 are formed in the drain contact via cavities 89 in contact with the drain regions 63, and contacts 86C are formed in the layer contact via cavities 87 in contact with the layer conductive via structures 86. Bit lines (not shown) are then formed in electrical contact with the drain contact via structures 88 and additional metal interconnect structures (not shown) and additional dielectric material layers (not shown) may be formed as needed to provide interconnection among various device components.

Referring to FIGS. 35F-35I , the dielectric fin portions 76F of the lateral isolation trench fill structure 76 form dielectric bridges to the first subset of the support pillar structures 20A. Specifically, the dielectric fin portions 76F comprise the source-electrode-level dielectric fins 76FS, the first-cap-level dielectric fins 76F1, and the second-cap-level dielectric fins 76F2. The dielectric fin portions 76F protrude laterally from the remaining portions of the lateral isolation trench fill structure 76 along the second horizontal direction hd2, and contact one or more respective support pillar structures 20A.

For example, as shown in FIG. 35F, the first subset of the support pillar structures 20A may be located in a pair of rows of support pillar structures 20 extending along the first horizontal direction hd1 adjacent to the respective lateral isolation trench fill structure 76. The dielectric fin portions 76F do not contact the second subset of the support pillar structures 20B. The second subset of the support pillar structures 20B may be located in rows distal from the lateral isolation trench fill structures 76, such that a row of the first subset of the support pillar structures 20A may be located between a respective lateral isolation trench fill structure 76 and one or more rows of the second subset of the support pillar structures 20B.

In the embodiment of FIG. 35F, each dielectric fin portion 76F (e.g., 76F2) contacts each single respective support pillar structure 20A located in a row of support pillar structures 20 directly adjacent to the respective lateral isolation trench fill structure 76.

In the embodiment of FIG. 35G, each dielectric fin portion 76F (e.g., 76F2) contacts a pair of adjacent support pillar structures 20A located in a row of support pillar structures 20 directly adjacent to the respective lateral isolation trench fill structure 76. In this embodiment, every third support pillar structure 20 located in a row of support pillar structures 20 directly adjacent to the respective lateral isolation trench fill structure 76 is not contacted by a respective dielectric fin portion 76F.

In the embodiment of FIG. 35H, each dielectric fin portion 76F (e.g., 76F2) contacts a single respective support pillar structure 20A located in a row of support pillar structures 20 directly adjacent to the respective lateral isolation trench fill structure 76. In this embodiment, every second and third support pillar structure 20 located in a row of support pillar structures 20 directly adjacent to the respective lateral isolation trench fill structure 76 is not contacted by a respective dielectric fin portion 76F.

In the embodiments of FIGS. 35F-35H , the dielectric fin portions 76F are staggered along the first horizontal direction hd1 on opposite sides of the respective lateral isolation trench fill structure 76. In the embodiment of FIG. 35I, the dielectric fin portions 76F are not staggered along the first horizontal direction hd1 on opposite sides of the respective lateral isolation trench fill structure 76. Thus, each dielectric fin portion 76F may protrude on two opposite sides of the respective lateral isolation trench fill structure 76 along the second horizontal direction. In this embodiment, each dielectric fin portion 76F may contact every other support pillar structure 20A on a first side of the respective lateral isolation trench fill structure 76, and a pair of support pillar structures 20A on the opposite second side of the respective lateral isolation trench fill structure 76. Thus, every other support pillar structure 20A is contacted on the first side and all support pillar structures 20A on the second side of the respective lateral isolation trench fill structure 76 are contacted by a respective dielectric fin portion 76F.

The dielectric fin portions 76F form dielectric bridges which contact the support pillar structures 20A, which reduce or prevent collapse, deflection and/or bowing of the alternating stacks into the lateral isolation trenches 79 during fabrication of the memory device. Furthermore, the dielectric bridges permit formation of the laterally-bulging portions LPB at the bottoms of all stacks during the same processing steps with a lower chance of collapse or bowing of the stacks. The laterally-bulging portions LPB maintain the desired width of the lateral isolation trench fill structure 76 in the lateral isolation trench 79 and prevent the lateral isolation trench 79 from becoming too narrow or closed off at the bottom of the stacks due to the taper of its sidewalls during etching.

Referring collectively to all drawings and according to various embodiments of the present disclosure, a device structure comprises: a pair of vertical layer stacks (132, 146, 170, 232, 246, 270, 332, 346, 370) that comprise insulating layers (132, 232, 332) and electrically conductive layers (146, 246, 346) that laterally extend along a first horizontal direction hd1 and are laterally spaced apart from each other along a second horizontal direction hd2 by a lateral isolation trench 79 that is filled with a lateral isolation trench fill structure 76; memory openings 49 vertically extending through a respective vertical layer stack (132, 146, 170, 232, 246, 270, 332, 346, 370) within the pair of vertical layer stacks (132, 146, 170, 232, 246, 270, 332, 346, 370); and memory opening fill structures 58 located in the memory openings 49, wherein each of the memory opening fill structures 58 comprises a respective vertical stack of memory elements (e.g., portions of the memory film 50) and a vertical semiconductor channel 60; and support pillar structures 20 vertically extending through the pair of vertical layer stacks, wherein dielectric bridges 76F connect a first subset of the support pillar structures 20A with the lateral isolation trench fill structure 76.

In one embodiment, each vertical layer stack (132, 146, 170, 232, 246, 270, 332, 346, 370) within the pair of vertical layer stacks (132, 146, 170, 232, 246, 270, 332, 346, 370) comprises, from bottom to top, a respective first-tier alternating stack (132, 146) including a vertically alternating sequence of first-tier insulating layers 132 and first-tier electrically conductive layers 146, a respective first-tier insulating cap layer 170, a respective second-tier alternating stack (232, 246) including a vertically alternating sequence of second-tier insulating layers 232 and second-tier electrically conductive layers 246, and a respective second-tier insulating cap layer 270. The lateral isolation trench fill structure 76 comprises a first laterally-bulging portion LBP1 between lower portions of the first-tier alternating stack (132, 146) and a second laterally-bulging portion LBP2 between lower portions of the second-tier alternating stacks (232, 246).

In one embodiment, the first laterally-bulging portion LBP1 laterally protrudes along the second horizontal direction hd2 with respect to an overlying first-tier wall portion WP1 of the lateral isolation trench fill structure 76; and the second laterally-bulging portion LBP2 laterally protrudes along the second horizontal direction hd2 with respect to an overlying second-tier wall portion WP2 of the lateral isolation trench fill structure 76. In one embodiment, the first-tier wall portion WP1 is located between the first laterally-bulging portion LBP1 and the second laterally-bulging portion LBP2; and the second-tier wall portion WP2 is located above the second laterally-bulging portion LBP2.

In one embodiment, the lateral isolation trench fill structure 76 comprises a pair of contoured lengthwise sidewalls that generally extend along the first horizontal direction hd1 with lateral modulations along the second horizontal direction hd2; and each of the pair of contoured lengthwise sidewalls comprises a respective first-tier lower lengthwise sidewall segment that is a sidewall of the first laterally-bulging portion LBP1, a respective first horizontal connecting surface that is adjoined to a top edge of the respective first-tier lower lengthwise sidewall segment, and a respective first-tier upper lengthwise sidewall segment that is a sidewall of the first-tier wall portion WP1.

In one embodiment, the respective horizontal connecting surface is a bottom surface of one of the first-tier insulating layers 132. In one embodiment, each of the pair of contoured lengthwise sidewalls comprises a respective second-tier lower lengthwise sidewall segment that is a sidewall of the second laterally-bulging portion LBP2, a respective second horizontal connecting surface that is adjoined to a top edge of the respective second-tier lower lengthwise sidewall segment, and a respective second-tier upper lengthwise sidewall segment that is a sidewall of the second-tier wall portion WP2.

In one embodiment, sidewalls of the first-tier wall portion WP1 have a respective taper angle in a vertical cross-sectional view in a vertical plane that is perpendicular to the first horizontal direction hd1; and a width of a bottom portion of the second-tier wall portion WP2 along the second horizontal direction hd2 is less than a width of a top portion of the first-tier wall portion WP1 along the second horizontal direction hd2.

In one embodiment, the dielectric bridges 76F comprise dielectric fin portions 76F of the lateral isolation trench fill structure 76 that laterally protrude from the lateral isolation trench fill structure along the second horizontal direction hd2. The dielectric fin portions 76F comprise first-tier-cap-level fins 76F1 and second-tier-cap-level fins overlying the first-tier-cap-level fins 76F2. In one embodiment, top surfaces of the first-tier-cap-level fins 76F1 are located within a horizontal plane including top surfaces of the first-tier insulating cap layers 170; and bottom surfaces of the first-tier-cap-level fins 76F1 are located within a horizontal plane including recessed horizontal surfaces of the first-tier insulating cap layers 170.

In one embodiment, the first-tier-cap-level fins 76F1 underlie the second laterally-bulging portion LBP2 and laterally protrude along the second horizontal direction hd2 from sidewalls of the second laterally-bulging portion LBP2. A first subset of the support pillar structures 20A comprises a respective laterally-protruding fin portion 20P located at a level of the first-tier insulating cap layers 170 and contacting a respective one of the first-tier-cap-level fins 76F1; and a second subset of the support pillar structures 20B is free of any laterally-protruding fin portion. In one embodiment, the laterally-protruding fin portions 20P of the first subset of the support pillar structures 20 has a same vertical thickness as the first-tier-cap-level fins 76F1 of the lateral isolation trench fill structure 76.

In one embodiment, a lateral spacing between the first-tier insulating cap layers 170 is less than a width of the second laterally-bulging portion LBP2 of the lateral isolation trench fill structure 76. In one embodiment, the lateral isolation trench fill structure 76 comprises air gaps (73, 77) located above and below the dielectric bridges 76F.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a pair of vertical layer stacks comprising alternating insulating and electrically conductive layers that laterally extend along a first horizontal direction and are laterally spaced apart from each other along a second horizontal direction by a lateral isolation trench that is filled with a lateral isolation trench fill structure;
memory openings vertically extending through a respective vertical layer stack within the pair of vertical layer stacks;
memory opening fill structures located in the memory openings, wherein each of the memory opening fill structures comprises a respective vertical stack of memory elements and a vertical semiconductor channel; and
support pillar structures vertically extending through the pair of vertical layer stacks, wherein dielectric bridges connect a first subset of the support pillar structures with the lateral isolation trench fill structure.

2. The device structure of claim 1, wherein:
each vertical layer stack within the pair of vertical layer stacks comprises, from bottom to top, a respective first-tier alternating stack including a vertically alternating sequence of first-tier insulating layers and first-tier electrically conductive layers, a respective first-tier insulating cap layer, a respective second-tier alternating stack including a vertically alternating sequence of second-tier insulating layers and second-tier electrically conductive layers, and a respective second-tier insulating cap layer; and
the lateral isolation trench fill structure comprises a first laterally-bulging portion between lower portions of the first-tier alternating stacks and a second laterally-bulging portion between lower portions of the second-tier alternating stacks.

3. The device structure of claim 2, wherein:
the first laterally-bulging portion laterally protrudes along the second horizontal direction with respect to an overlying first-tier wall portion of the lateral isolation trench fill structure; and
the second laterally-bulging portion laterally protrudes along the second horizontal direction with respect to an overlying second-tier wall portion of the lateral isolation trench fill structure.

4. The device structure of claim 3, wherein:
the first-tier wall portion is located between the first laterally-bulging portion and the second laterally-bulging portion; and
the second-tier wall portion is located above the second laterally-bulging portion.

5. The device structure of claim 4, wherein:
the lateral isolation trench fill structure comprises a pair of contoured lengthwise sidewalls that generally extend along the first horizontal direction with lateral modulations along the second horizontal direction; and
each of the pair of contoured lengthwise sidewalls comprises a respective first-tier lower lengthwise sidewall segment that is a sidewall of the first laterally-bulging portion, a respective first horizontal connecting surface that is adjoined to a top edge of the respective first-tier lower lengthwise sidewall segment, and a respective first-tier upper lengthwise sidewall segment that is a sidewall of the first-tier wall portion.

6. The device structure of claim 5, wherein the respective horizontal connecting surface is a bottom surface of one of the first-tier insulating layers.

7. The device structure of claim 5, wherein each of the pair of contoured lengthwise sidewalls further comprises a respective second-tier lower lengthwise sidewall segment that is a sidewall of the second laterally-bulging portion, a respective second horizontal connecting surface that is adjoined to a top edge of the respective second-tier lower lengthwise sidewall segment, and a respective second-tier upper lengthwise sidewall segment that is a sidewall of the second-tier wall portion.

8. The device structure of claim 7, wherein the lateral isolation trench fill structure further comprises:

9. The device structure of claim 4, wherein:
sidewalls of the first-tier wall portion have a respective taper angle in a vertical cross-sectional view in a vertical plane that is perpendicular to the first horizontal direction; and
a width of a bottom portion of the second-tier wall portion along the second horizontal direction is less than a width of a top portion of the first-tier wall portion along the second horizontal direction.

10. The device structure of claim 9, wherein the dielectric bridges comprise dielectric fin portions of the lateral isolation trench fill structure that laterally protrude from the lateral isolation trench fill structure along the second horizontal direction.

11. The device structure of claim 10, wherein:
the dielectric fin portions comprise first-tier-cap-level fins and second-tier-cap-level fins overlying the first-tier-cap-level fins;
top surfaces of the first-tier-cap-level fins are located within a horizontal plane including top surfaces of the first-tier insulating cap layers;
bottom surfaces of the first-tier-cap-level fins are located within a horizontal plane including recessed horizontal surfaces of the first-tier insulating cap layers;
the first-tier-cap-level fins underlie the second laterally-bulging portion and laterally protrude along the second horizontal direction from sidewalls of the second laterally-bulging portion.

12. The device structure of claim 11, wherein:
the first subset of the support pillar structures comprises a respective laterally-protruding fin portion located at a level of the first-tier insulating cap layers and contacting a respective one of the first-tier-cap-level fins;
a second subset of the support pillar structures is free of any laterally-protruding fin portion; and
the laterally-protruding fin portions of the first subset of the support pillar structures has a same vertical thickness as the first-tier-cap-level fins of the lateral isolation trench fill structure.

13. The device structure of claim 3, wherein a lateral spacing between the first-tier insulating cap layers is less than a width of the second laterally-bulging portion of the lateral isolation trench fill structure.

14. The device structure of claim 1, wherein the lateral isolation trench fill structure comprises air gaps located above and below the dielectric bridges.

15. A method of forming a device structure, comprising:
forming a pair of vertical layer stacks embedding memory opening fill structures over a substrate, wherein the vertical layer stacks laterally extend along a first horizontal direction and are laterally spaced apart from each other along a second horizontal direction by a lateral isolation trench, wherein each vertical layer stack within the pair of vertical layer stacks comprises, from bottom to top, a respective first-tier alternating stack of first-tier insulating layers and first-tier sacrificial material layers, a respective first-tier insulating cap layer embedding first sacrificial plates, a respective second-tier alternating stack of second-tier insulating layers and second-tier sacrificial material layers, and a respective second-tier insulating cap layer, and wherein each of the memory openings vertically extends through a respective vertical layer stack within the pair of vertical layer stacks and comprises a respective vertical stack of memory elements;
forming first laterally-extending voids by removing the first sacrificial plates selectively to the first-tier insulating cap layer, the first-tier alternating stack, and the second-tier alternating stack;
selectively etching lower portions of the second-tier alternating stacks without etching upper portions of the second-tier alternating stacks and without etching upper portions of the first-tier alternating stacks, wherein the lateral isolation trench is widened at a level of the lower portions of the second-tier alternating stacks; and
replacing the first-tier sacrificial material layers and the second-tier sacrificial material layers with first-tier electrically conductive layers and second-tier electrically conductive layers, respectively.

16. The method of claim 15, further comprising:
forming a sacrificial lateral isolation trench fill structure in the lateral isolation trench;
forming support openings through the pair of vertical layer stacks, wherein sidewalls of the first sacrificial plates are exposed to a first subset of the support openings; and
performing a first selective isotropic etch process that etches the sacrificial material plates without etching the first-tier alternating stacks, the second-tier alternating stacks, and the first-tier insulating cap layer, whereby the first laterally-extending voids are formed.

17. The method of claim 16, further comprising performing a second selective isotropic etch process that etches proximal portions of the sacrificial lateral isolation trench structure around the first laterally-extending voids, wherein first inter-tier voids are formed within the sacrificial lateral isolation trench fill structure.

18. The method of claim 17, further comprising:
performing a third selective isotropic etch process that etches portions of the second-tier sacrificial material layers selectively to materials of the second-tier insulating layers and the first-tier insulating cap layers, wherein fin-shaped voids are formed around the first inter-tier voids; and
performing a fourth selective isotropic etch process that isotropically recesses the second-tier insulating layers and the first-tier insulating layers after performing the third selective isotropic etch process, such that the lateral isolation trench is widened at the level of the lower portions of the second-tier alternating stacks;

19. The method of claim 18, further comprising:
forming support pillar structures extending through the pair of vertical layer stacks;
removing the sacrificial lateral isolation trench fill structure; and
forming a lateral isolation trench fill structure in the lateral isolation trench.

20. The method of claim 19, wherein:
dielectric fin portions of the sacrificial lateral isolation trench fill structure filling the fin-shaped voids comprise dielectric bridges which connect the lateral isolation trench fill structure to a subset of the support pillar structures;
the sacrificial lateral isolation trench fill structure comprises a first-tier sacrificial lateral isolation trench fill material portion, a second-tier sacrificial lateral isolation trench fill material portion, and an etch-stop liner located between the first-tier sacrificial lateral isolation trench fill material portion and the second-tier sacrificial lateral isolation trench fill material portion; and
the etch-stop liner prevents etching of an upper portion of the first-tier sacrificial lateral isolation trench fill material portion during the second selective isotropic etch process.
